(19) United States
(12) Patent Application Publication
(10) Pub. No.: US 2007/0164342 A1
(43) Pub. Date: Jul. 19, 2007

(54) Semiconductor memory device and method of manufacturing the same

(75) Inventors: Tsutomu Okazaki, Tokyo (JP); Motoi Ashida, Tokyo (JP); Hiroji Ozaki, Tokyo (JP); Tsuyoshi Koga, Tokyo (JP); Daisuke Okada, Tokyo (JP); Masamichi Matsuoka, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/651,965

(22) Filed: Jan. 11, 2007

(30) Foreign Application Priority Data
Jan. 13, 2006 (JP) 2006-006026 (P)

(51) Int. Cl. H01L 29/76

(52) U.S. Cl. 257/314

(57) ABSTRACT

A polysilicon film forming a memory gate interconnection and the like includes a part extending from a part positioned on one side surface of a control gate interconnection to a side opposite to a side where the control gate interconnection is positioned, and that part serves as a pad portion. A contact hole is formed to expose the pad portion. The height of a part of the polysilicon film that is positioned on one side surface of the control gate interconnection is set equal to or lower than the height of the control gate interconnection so that the polysilicon film forming a memory gate interconnection and the like does not two-dimensionally overlap the control gate interconnection. Therefore, a semiconductor memory device with increased process margin can be obtained.

### BACKGROUND OF THE INVENTION

1. Field of the Invention

The present invention relates to a semiconductor memory device and a method of manufacturing the same, and more particularly to a nonvolatile semiconductor memory device having a control gate electrode and a memory gate electrode and a method of manufacturing the same.

2. Description of the Background Art

Semiconductor memory devices include a nonvolatile semiconductor memory device in which information is not lost even when the power is turned off. As one of such nonvolatile semiconductor memory devices, Japanese Patent Laying-Open No. 2004-186452 proposes a nonvolatile semiconductor memory device including two MISFET (Metal Insulator Semiconductor Field Effect Transistor) of a control transistor including a control gate electrode and a memory transistor including a memory gate electrode in a memory cell.

In this semiconductor memory device, a control gate electrode is formed on a surface of a semiconductor substrate with a gate insulating film interposed. A memory gate electrode is formed like a sidewall on a side surface of the control gate electrode with an ONO (Oxide Nitride Oxide) film interposed on a surface of the semiconductor substrate. The ONO film extends from the surface of the semiconductor substrate to the side surface of the control gate electrode to be interposed between the side surface of the control gate electrode and the memory gate electrode. A source region is formed in a region of the semiconductor substrate that is positioned on one side across the control gate electrode and the memory gate electrode, and a drain region is formed in a region of the semiconductor substrate on the other side. The operations of writing, reading and erasure of a memory cell are performed by applying respective prescribed voltages to the control gate electrode, the memory gate electrode, the source region, and the drain region.

A method of manufacturing the semiconductor memory device will now be described. First, a control gate electrode and a control gate interconnection are formed on a semiconductor substrate, and an ONO film is formed to cover the control gate electrode and the like. A polysilicon film is formed on the ONO film. A prescribed resist pattern for forming a pad portion is formed on the polysilicon film. Using the resist pattern as a mask, anisotropic etching is performed on the polysilicon film to leave a part of the polysilicon film that serves as a pad portion and to leave the sidewall-like parts of the polysilicon film with the ONO film interposed on opposite side surfaces of the control gate electrode and the like and remove the remaining part of the polysilicon film.

Then, of the parts of the polysilicon film positioned on opposite side surfaces of the control gate electrode and the like, the part of the polysilicon film that is positioned on one side surface is left and the part of the polysilicon film that is positioned on the other side surface is removed. Thus, a memory gate electrode and a memory gate interconnection like a side wall are formed on one side surface of the control gate electrode and the like. Then, an interlayer insulating film is formed to cover the control gate electrode and the like and the memory gate electrode and the like, and a contact hole is formed in the interlayer insulating film to expose the pad portion and the like.

Then, a film serving as a prescribed plug is formed on the interlayer insulating film to fill in the contact hole, and CMP (Chemical Mechanical Polishing) is performed on the film serving as a plug to remove a part of the film that is positioned on the upper surface of the interlayer insulating film thereby forming a plug in the contact hole. Thereafter, a prescribed interconnection to be connected to the plug is formed on the surface of the interlayer insulating film, thereby forming a main part of a nonvolatile semiconductor memory device. The conventional nonvolatile semiconductor memory device is formed in the foregoing manner.

However, the conventional semiconductor memory device has the following problems. As described above, in order to operate a memory cell, a control gate electrode, a memory gate electrode, a source region and a drain region receive respective prescribed voltages. In particular, a pad portion is formed to apply such a prescribed voltage to the memory gate electrode. The pad portion is formed of a part of the same film with a memory gate electrode and a memory gate interconnection connecting the memory gate electrode by performing prescribed processing on the polysilicon film.

In the photolithography for forming the pad portion, a resist pattern is formed such that the pad portion is reliably connected to a part of the polysilicon film that serves as a memory gate interconnection. In other words, in view of the variations in photolithography, the resist pattern is formed to cover a part of the upper surface of the part serving as a control gate interconnection from the part serving as a memory gate interconnection to a part serving as a control gate interconnection.

Therefore, after etching is performed using the resist pattern as a mask, the polysilicon film is positioned in a continuous manner from the pad portion to immediately above the part serving as a control gate interconnection, so that the polysilicon film partially overlies the part serving as a control gate interconnection. In other words, the polysilicon film forming the memory gate interconnection and the like has a part that two-dimensionally overlaps the control gate interconnection.

The interlayer insulating film which covers such memory gate interconnection and the like requires such a thickness that prevents a part of the polysilicon film that overlies the memory gate interconnection from being exposed by the CMP process to form a plug in the contact hole. On the other hand, if the thickness of the interlayer insulating film is increased to ensure that such a part of the polysilicon film is not exposed by the CMP process, the aspect ratio (the depth/the opening diameter) of the contact hole is increased, so that it becomes difficult to open a contact hole with high dimensional accuracy thereby reducing the process margin.

### SUMMARY OF THE INVENTION

The present invention is made to solve the aforementioned problems. An object of the present invention is to provide a semiconductor memory device with increased process margin. Another object of the present invention is to provide a method of manufacturing such a semiconductor memory device.

A semiconductor memory device in accordance with the present invention includes a first conductor portion, a second conductor portion, an interlayer insulating film, and a contact member. The first conductor portion is formed on a surface of a semiconductor substrate to have a prescribed height and opposite side surfaces and extend in a first direction. The second conductor portion is formed on one side surface of the opposite side surfaces of the first conductor portion to be electrically separated from the first conductor portion. The interlayer insulating film is formed on the semiconductor substrate to cover the first conductor portion and the second conductor portion. The contact member is formed to pass through the interlayer insulating film. The second conductor portion includes a first protrusion portion extending from a part positioned on the one side surface of the first conductor portion to a side opposite to a side where the first conductor portion is positioned and being in contact with the contact member so that a prescribed voltage is applied to the second conductor portion. The height of a part of the second conductor portion that is positioned on the one side surface is set to be at most the height of the first conductor portion such that the second conductor portion does not two-dimensionally overlap the first conductor portion.

A method of manufacturing a semiconductor memory device in accordance with the present invention includes the following steps. A first conductor portion having a prescribed height and opposite side surfaces and extending in a first direction is formed on a main surface of a semiconductor substrate. A conductive layer is formed on a surface of the semiconductor substrate with a first insulating film interposed to cover the first conductor portion. A resist pattern is formed on the conductive layer by performing a photolithography process using a prescribed mask. A voltage application portion for applying a prescribed voltage is formed by performing processing on the conductive layer using the resist pattern as a mask. By leaving a part of the conductive layer that is positioned on a side of one side surface of the first conductor portion and removing a part of the conductive layer positioned in the other part, a second conductor portion including the voltage application portion is formed on the one side surface of the first conductor portion with the first insulating film interposed. An interlayer insulating film is formed to cover the first conductor portion and the second conductor portion. An opening portion is formed in the interlayer insulating film to expose the voltage application portion in the second conductor portion, and a contact member is formed in the opening portion to be electrically connected to the voltage application portion. In the step of forming a resist pattern, an exposure process is performed on a resist coated on the semiconductor substrate such that the resist is left after development as a result of poor resolution, from the resist pattern left after development based on the prescribed mask to a part of the conductive layer that covers the one side surface of the first conductor portion, whereby a resist pattern is formed as the resist pattern including a resist pattern formed based on the prescribed mask as a first resist pattern and a resist left as a result of poor resolution as a second resist pattern.

In the semiconductor memory device in accordance with the present invention, the second conductor portion includes a first protrusion portion extending from a part positioned on one side surface of the first conductor portion to a side opposite to a side where the first conductor portion is positioned and being in contact with the contact member. The height of a part of the second conductor portion that is positioned on the one side surface is set equal to or lower than the height of the first conductor portion such that the second conductor portion does not two-dimensionally overlap the first conductor portion. Therefore, a contact hole for providing a contact member can be formed accurately with reduced thickness of the interlayer insulating film, thereby increasing the process margin.

In the method of manufacturing a semiconductor memory device in accordance with the present invention, an exposure process is performed on the resist coated on the semiconductor substrate such that the resist is left after development as a result of poor resolution, from the resist pattern left after development based on a prescribed mask to a part of the conductive layer that covers one side surface of the first conductor portion. A resist pattern is formed as such a resist pattern including a resist pattern formed based on a prescribed mask as a first resist pattern and a resist left as a result of poor resolution as a second resist pattern. Therefore, the conductive layer does not two-dimensionally overlap the first conductor portion, so that a contact hole for providing a contact member can be formed accurately with reduced thickness of the interlayer insulating film, thereby increasing the process margin.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partial plan view of a nonvolatile semiconductor memory device in accordance with a first embodiment of the present invention.

FIG. 2 is a cross sectional view taken along line II-II shown in FIG. 1 in the first embodiment.

FIG. 3 is a cross sectional view taken along line III-III shown in FIG. 1 in the first embodiment.

FIG. 4 shows a circuit of a memory cell in the first embodiment.

FIG. 5 is a schematic cross sectional view of a memory cell to illustrate an operation of the nonvolatile semiconductor memory device in the first embodiment.

FIG. 6 shows an example of a voltage applied to each part of a memory cell to illustrate an operation of the nonvolatile semiconductor memory device in the first embodiment.

FIG. 7 is a cross sectional view showing a step of a method of manufacturing the nonvolatile semiconductor memory device shown in FIG. 1-FIG. 3 in the first embodiment.

FIG. 8 is a cross sectional view showing a step performed after the step shown in FIG. 7 in the first embodiment.

FIG. 9 is a cross sectional view showing a step performed after the step shown in FIG. 8 in the first embodiment.

FIG. 10 is a partial plan view showing a step performed after the step shown in FIG. 9 in the first embodiment.

FIG. 11 is a cross sectional view taken along line XI-XI shown in FIG. 10 in the first embodiment.

FIG. 12 is a cross sectional view showing a step performed after the step shown in FIG. 11 in the first embodiment.

FIG. 13 is a cross sectional view showing a step performed after the step shown in FIG. 12 in the first embodiment.

FIG. 14 is a cross sectional view showing a step performed after the step shown in FIG. 13 in the first embodiment.

FIG. 15 is a cross sectional view showing a step performed after the step shown in FIG. 14 in the first embodiment.

FIG. 16 is a cross sectional view showing a step performed after the step shown in FIG. 15 in the first embodiment.

FIG. 17 is a cross sectional view showing a step performed after the step shown in FIG. 16 in the first embodiment.

FIG. 18 is a cross sectional view showing a step performed after the step shown in FIG. 17 in the first embodiment.

FIG. 19 is a cross sectional view showing a step performed after the step shown in FIG. 18 in the first embodiment.

FIG. 20 is a cross sectional view showing a step performed after the step shown in FIG. 19 in the first embodiment.

FIG. 21 is a cross sectional view showing a step performed after the step shown in FIG. 20 in the first embodiment.

FIG. 22 is a cross sectional view showing a step performed after the step shown in FIG. 21 in the first embodiment.

FIG. 23 is a cross sectional view showing a step performed after the step shown in FIG. 22 in the first embodiment.

FIG. 24 is a cross sectional view showing a step performed after the step shown in FIG. 23 in the first embodiment.

FIG. 25 is a partial plan view of a nonvolatile semiconductor memory device in accordance with a second embodiment of the present invention.

FIG. 26 is a cross sectional view taken along line XXVI-XXVI shown in FIG. 25 in the second embodiment.

FIG. 27 is a cross sectional view taken along line XXVII-XXVII shown in FIG. 25 in the second embodiment.

FIG. 28 is a cross sectional view showing a step of a method of manufacturing the nonvolatile semiconductor memory device shown in FIG. 25-FIG. 27 in the second embodiment.

FIG. 29 is a cross sectional view showing a step performed after the step shown in FIG. 28 in the second embodiment.

FIG. 30 is a cross sectional view showing a step performed after the step shown in FIG. 29 in the second embodiment.

FIG. 31 is a partial plan view showing a step performed after the step shown in FIG. 30 in the second embodiment.

FIG. 32 is a cross sectional view taken along line XXXII-XXXII shown in FIG. 31 in the second embodiment.

FIG. 33 is a cross sectional view showing a step performed after the step shown in FIG. 32 in the second embodiment.

FIG. 34 is a cross sectional view showing a step performed after the step shown in FIG. 33 in the second embodiment.

FIG. 35 is a cross sectional view showing a step performed after the step shown in FIG. 34 in the second embodiment.

FIG. 36 is a cross sectional view showing a step performed after the step shown in FIG. 35 in the second embodiment.

FIG. 37 is a cross sectional view showing a step performed after the step shown in FIG. 36 in the second embodiment.

FIG. 38 is a cross sectional view showing a step performed after the step shown in FIG. 37 in the second embodiment.

FIG. 39 is a cross sectional view showing a step performed after the step shown in FIG. 38 in the second embodiment.

FIG. 40 is a cross sectional view showing a step performed after the step shown in FIG. 39 in the second embodiment.

FIG. 41 is a cross sectional view showing a step performed after the step shown in FIG. 40 in the second embodiment.

FIG. 42 is a cross sectional view showing a step performed after the step shown in FIG. 41 in the second embodiment.

FIG. 43 is a partial plan view of a nonvolatile semiconductor memory device in accordance with a third embodiment of the present invention.

FIG. 44 is a cross sectional view taken along line XLIV-XLIV shown in FIG. 43 in the third embodiment.

FIG. 45 is a cross sectional view taken along line XLV-XLV shown in FIG. 43 in the third embodiment.

FIG. 46 is a cross sectional view showing a step of a method of manufacturing the nonvolatile semiconductor memory device shown in FIG. 43-FIG. 45 in the third embodiment.

FIG. 47 is a cross sectional view showing a step performed after the step shown in FIG. 46 in the third embodiment.

FIG. 48 is a partial plan view showing a step performed after the step shown in FIG. 47 in the third embodiment.

FIG. 49 is a cross sectional view taken along line XLIX-XLIX shown in FIG. 48 in the third embodiment.

FIG. 50 is a cross sectional view showing a step performed after the step shown in FIG. 49 in the third embodiment.

FIG. 51 is a cross sectional view showing a step performed after the step shown in FIG. 50 in the third embodiment.

FIG. 52 is a partial plan view of a nonvolatile semiconductor memory device in accordance with a fourth embodiment of the present invention.

FIG. 53 is a cross sectional view taken along line LIII-LIII shown in FIG. 52 in the fourth embodiment.

FIG. 54 is a cross sectional view taken along line LIV-LIV shown in FIG. 52 in the fourth embodiment.

FIG. 55 is a cross sectional view showing a step of a method of manufacturing the nonvolatile semiconductor memory device shown in FIG. 52-FIG. 54 in the fourth embodiment.

FIG. 56 is a cross sectional view showing a step performed after the step shown in FIG. 55 in the fourth embodiment.

FIG. 57 is a partial plan view showing a step performed after the step shown in FIG. 56 in the fourth embodiment.

FIG. 58 is a cross sectional view taken along line LVIII-LVIII shown in FIG. 57 in the fourth embodiment.

FIG. 59 is a cross sectional view showing a step performed after the step shown in FIG. 58 in the fourth embodiment.

FIG. 60 is a cross sectional view showing a step performed after the step shown in FIG. 59 in the fourth embodiment.

### DESCRIPTION OF THE PREFERRED EMBODIMENTS

### First Embodiment

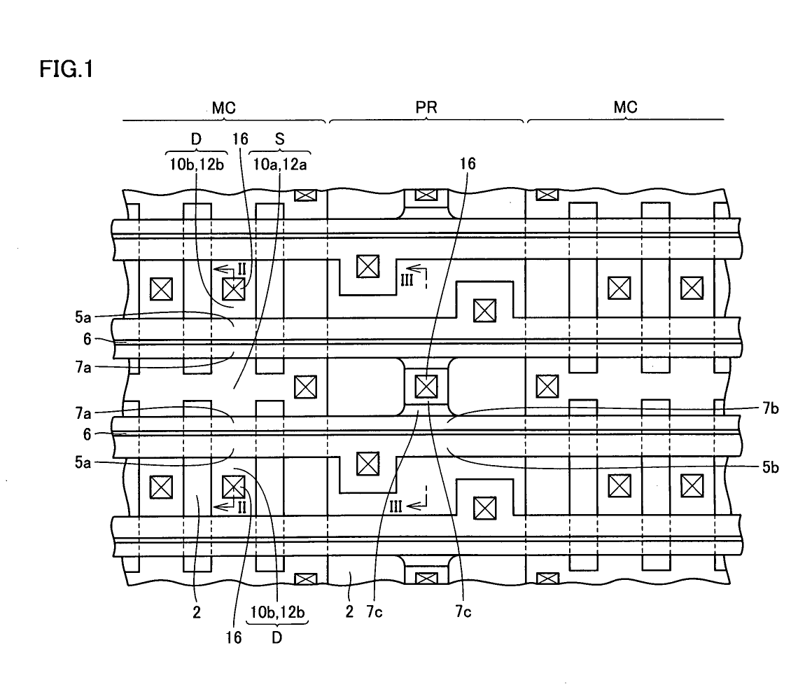

A nonvolatile semiconductor memory device in accordance with a first embodiment of the present invention will be described. As shown in FIG. 1, a memory cell region MC and a peripheral circuit region PR which are separated by an element isolation insulating film (STI) 2 are formed on a surface of a semiconductor substrate. A plurality of memory cells are formed in the region of the semiconductor substrate of the memory cell region MC. A control gate electrode 5a and a memory gate electrode 7a are formed in one memory cell. An ONO film is interposed between control gate electrode 5a and memory gate electrode 7a.

A low concentration impurity region 10a and a high concentration impurity region 12a are formed as a source region in a region of the semiconductor substrate that is positioned on one side across control gate electrode 5a and memory gate electrode 7a, and a low concentration impurity region 10b and a high concentration impurity region 12b are formed as a drain region in a region of the semiconductor substrate on the other side.

A control gate interconnection 5b electrically connecting control gate electrodes 5a to each other is formed to traverse the region of the semiconductor substrate of memory cell region MC, and a memory gate interconnection 7b electrically connecting memory gate electrodes 7a to each other is formed to traverse the region of the semiconductor substrate of the memory cell region.

In addition, a pad portion 7c for applying a prescribed voltage to memory gate electrode 7a is formed in a prescribed region on a surface of element isolation insulating film 2 in peripheral circuit region PR. Pad portion 7c is formed to be connected to each of two memory gate interconnections 7b extending in parallel and adjacent to each other.

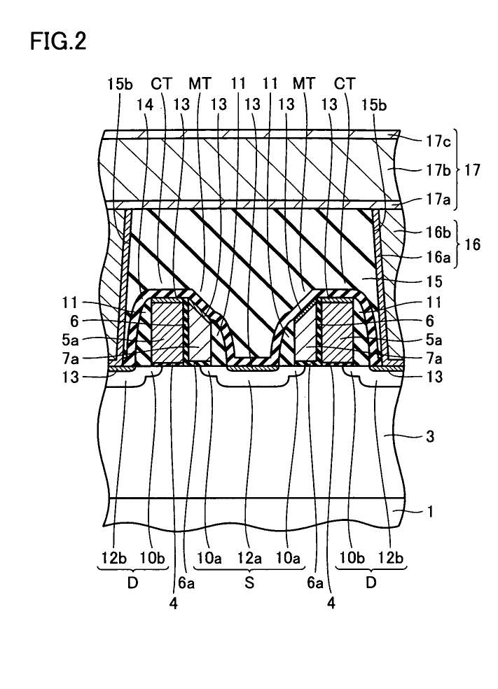

The structure of a memory cell will now be described in detail. As shown in FIG. 2, a well region 3 of a prescribed conductivity type is formed at a surface of a semiconductor substrate 1 and in the vicinity thereof. Control gate electrode 5a is formed on that surface of semiconductor substrate 1 which forms well region 3 with a control gate insulating film 4 interposed thereon. Sidewall-like memory gate electrode 7a is formed on one side surface of the opposite side surfaces of control gate electrode 5a. Memory gate electrode 7a is formed on a surface of semiconductor substrate 1 with an ONO film 6 interposed. ONO film 6 extends from the surface of semiconductor substrate 1 onto the one side surface of control gate electrode 5a to be interposed between the side surface of control gate electrode 5a and memory gate electrode 7a.

In the region of semiconductor substrate 1 that is positioned on the side opposite to the side where memory gate electrode 7a is positioned across control gate electrode 5a, low concentration impurity region 10b and high concentration impurity region 12b are formed as a drain region D. On the other hand, in the region of semiconductor substrate 1 positioned on the side opposite to the side where control gate electrode 5a is positioned across memory gate electrode 7a, low concentration impurity region 10a and high concentration impurity region 12a are formed as a source region S. Thus, a control transistor CT including a control gate electrode and a memory transistor MT including memory gate electrode 7a are formed.

A metal silicide film 13 is formed on each of the surface of control gate electrode 5a, the surface of memory gate electrode 7a, and the surfaces of high concentration impurity regions 12a, 12b. A sidewall insulating film 11 is formed on the other side surface of control gate electrode 5a. Sidewall insulating film 11 is also formed on one side surface of memory gate electrode 7a. A silicon nitride film 14 is formed on semiconductor substrate 1 to cover control gate electrode 5a and memory gate electrode 7a.

An interlayer insulating film 15 is formed to cover silicon nitride film 14. A contact hole 15b is formed in interlayer insulating film 15 to expose the surface of drain region D. A plug 16 including a first layer 16a and a second layer 16b each made of a prescribed material is formed in contact hole 15b. An interconnection 17 electrically connected to plug 16 is formed on interlayer insulating film 15. Interconnection 17 includes a first layer 17a, a second layer 17b and a third layer 17c each made of a prescribed material.

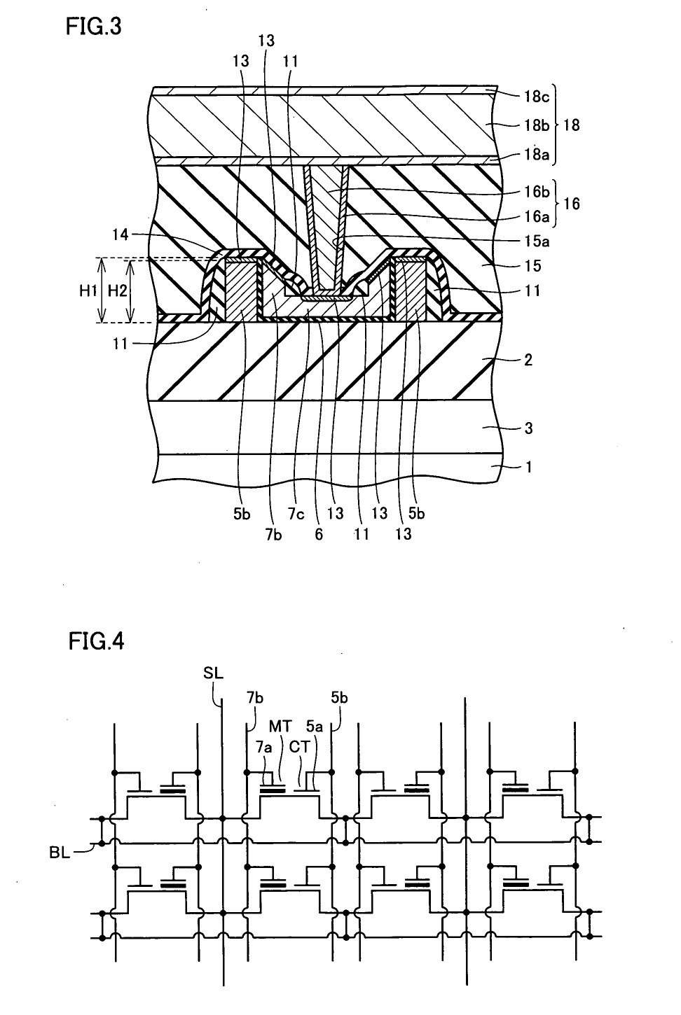

The structure of pad portion 7c and the region in the vicinity thereof will now be described in detail. As shown in FIG. 3, element isolation insulating film (STI: Shallow Trench Isolation) 2 is formed in a prescribed region of semiconductor substrate 1. Two control gate interconnections 5b spaced apart from each other are formed on the surface of element isolation insulating film 2. Memory gate interconnection 7b is formed on each of the side surfaces opposing to each other of two control gate electrodes 5b with ONO film 6 interposed. That part of polysilicon film 7 which forms these opposing memory gate interconnections 7b corresponds to a pair of opposing portions. Pad portion 7c (a first protrusion portion) connected to both of one memory gate interconnection 7b and the other memory gate interconnection 7b is formed between one memory gate interconnection 7b and the other memory gate interconnection 7b. ONO film 6 is interposed between pad portion 7c and element isolation insulating film 2.

Metal silicide film 13 is formed on each of the surface of control gate interconnection 5b, the surface of memory gate interconnection 7b and the surface of pad portion 7c. Sidewall insulating film 11 is formed on the side surface on the side opposite to the side where two control gate interconnections 5b are opposing to each other. Silicon nitride film 14 is formed on semiconductor substrate 1 to cover control gate interconnections 5b and memory gate interconnections 7b. Interlayer insulating film 15 is formed to cover silicon nitride film 14. Contact hole 15a is formed in interlayer insulating film 15 to expose the surface of pad portion 7c.

Plug 16 formed of first layer 16a and second layer 16b each made of a prescribed material is formed in contact hole 15a. An interconnection 18 electrically connected to plug 16 is formed on interlayer insulating film 15. Interconnection 18 includes a first layer 18a, a second layer 18b and a third layer 18c each made of a prescribed material. As described later, control gate electrode 5a and control gate interconnection 5b are each formed of a part of the same film. Memory gate electrode 7a, memory gate interconnection 7b and pad portion 7c are also each formed of a part of the same film.

The operation of a memory cell will now be described. First, in a plurality of memory cells formed like a matrix in the memory cell region, as shown in FIG. 4, each of memory gate electrodes 7a of memory transistors MT arranged in the column direction (the longitudinal direction) is electrically connected to memory gate interconnection 7b, and each of control gate electrodes 5a of control transistors CT is electrically connected to control gate interconnection 5b. Each of the source regions of the memory cells arranged in the column direction is connected to a source line SL, and each of the drain regions of the memory cells arranged in the row direction (the lateral direction) is connected to a bit line BL.

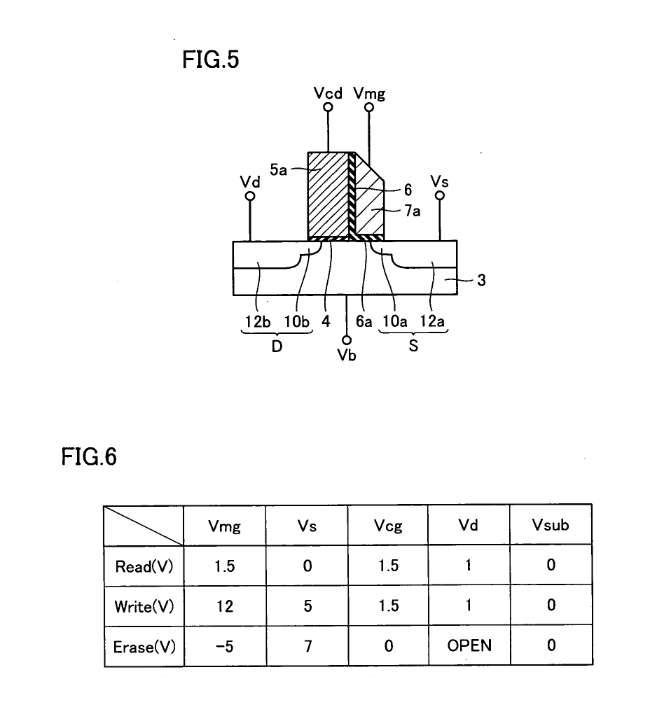

For writing, reading and erasure for the memory cell, control gate electrode 5a, memory gate electrode 7a, source region S and drain region D receive their respective prescribed voltages. Then, the writing operation is performed by setting, for example, voltage Vcg=1.5V, voltage Vmg=12V, voltage Vs=5V, voltage Vd=1V, Vsub=0V as shown in FIG. 6, where Vcg is a voltage applied to control gate electrode 5a, voltage Vmg is a voltage applied to memory gate electrode 7a, voltage Vs is a voltage applied to source region S, and voltage Vd is a voltage applied to drain region D, and voltage Vsub is a voltage applied to the semiconductor substrate, as shown in FIG. 5.

Here, hot electrons are produced in the region (channel region) of the semiconductor substrate that is positioned immediately below memory gate electrode 7a and selection gate electrode 5a, and the produced hot electrons are locally injected in the selection gate electrode 5a side of the silicon nitride film of ONO film 6 interposed between memory gate electrode 7a and semiconductor substrate 1. The injected hot electrons are thus trapped in that silicon nitride film. Accordingly, the threshold voltage of memory transistor MT rises.

The erasure operation is performed by setting, for example, voltage Vcg=0V, voltage Vmg=−5V, voltage Vs=7V, voltage Vd=open, Vsub=0V, as shown in FIG. 6. Here, holes are produced by the inter-band tunnel effect, and the produced holes are accelerated by the electric field to be injected to the silicon nitride film of ONO film 6. Accordingly, the threshold voltage of memory transistor MT drops.

The reading operation is performed by setting, for example, voltage Vcg=1.5V, voltage Vmg=1.5V, voltage Vs=0V, voltage Vd=1V, Vsub=0V, as shown in FIG. 6. Here, when voltage Vmg applied to memory gate electrode 7a in the reading operation is set at a voltage between the threshold voltage of the memory transistor in the writing state and the threshold voltage of the memory transistor in the erasure state. Accordingly, it is determined whether or not information is written in memory transistor MT.

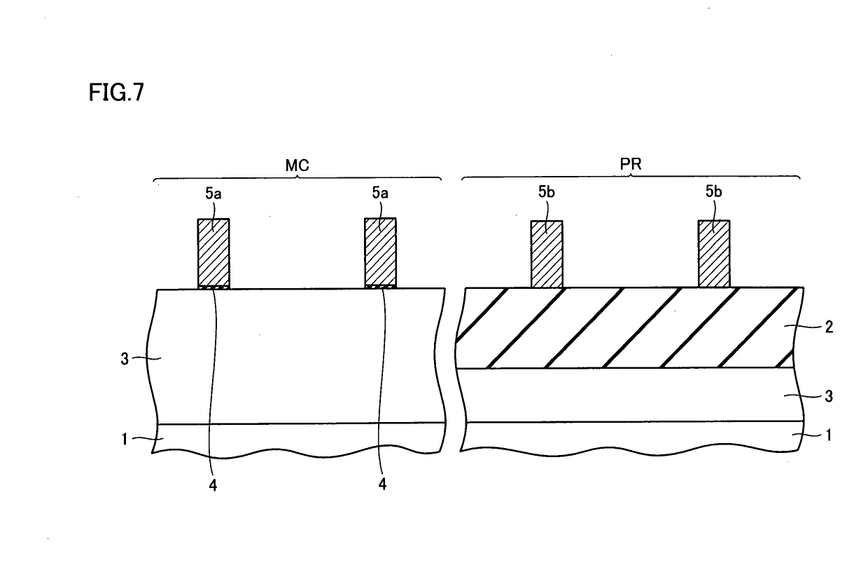

A method of manufacturing the nonvolatile semiconductor memory device as described above will now be described. First, as shown in FIG. 7, element isolation insulating film (STI) 2 and well region 3 for forming an element formation region such as a memory cell region are formed on a surface of a semiconductor substrate. Then, a polysilicon film serving as a control gate electrode, a control gate interconnection and the like is formed with an insulating film serving as a gate insulating film interposed on the surface of semiconductor substrate 1 (neither shown). Control gate electrode 5a is formed with control gate insulating film 4 interposed on the surface of semiconductor substrate 1 in memory cell region MC by performing prescribed photolithography and processing on the polysilicon film and the insulating film. Control gate interconnection 5b connected to control gate electrode 5a is formed in peripheral circuit region PR.

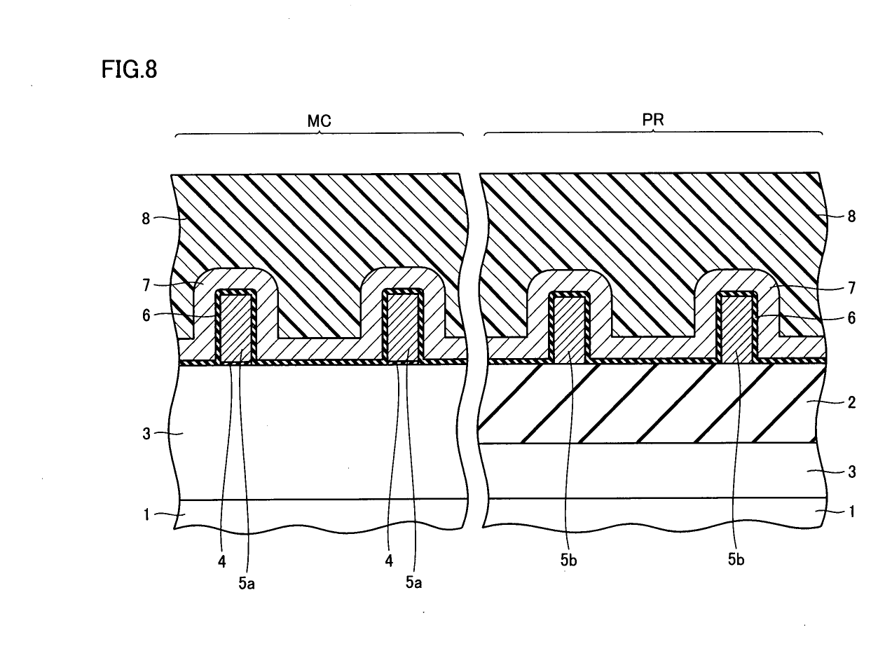

Next, as shown in FIG. 8, a silicon oxide film, a silicon nitride film and a silicon oxide film are successively deposited, for example, by CVD (Chemical Vapor Deposition) on semiconductor substrate 1 to cover control gate electrode 5a and control gate interconnection 5b, resulting in ONO film 6. Then, polysilicon film 7 serving as a memory gate electrode, a memory gate interconnection, a pad portion and the like is formed to cover ONO film 6. A photoresist 8 for forming a pad portion is coated on polysilicon film 7.

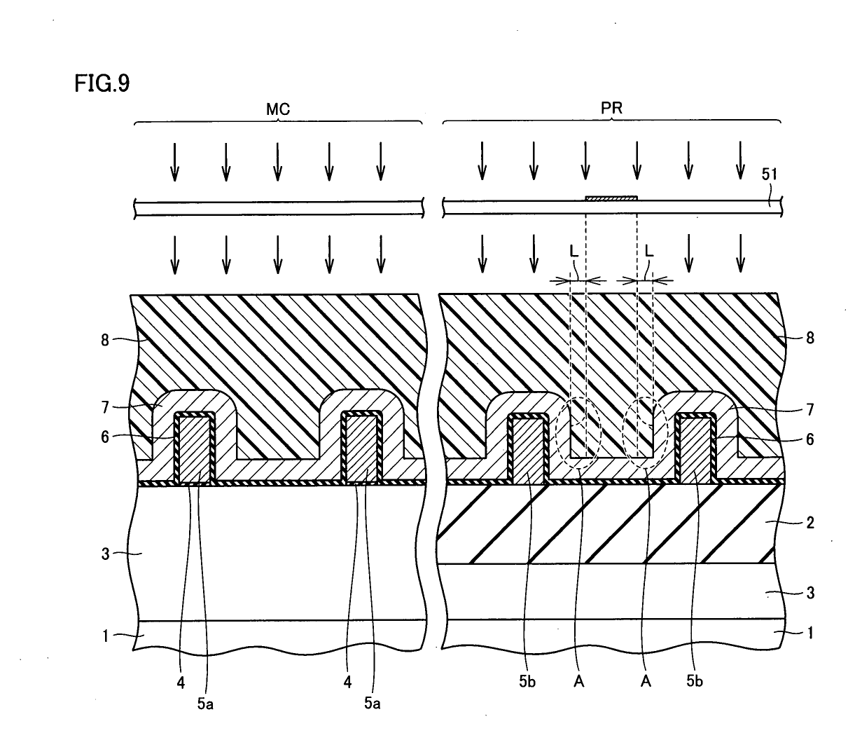

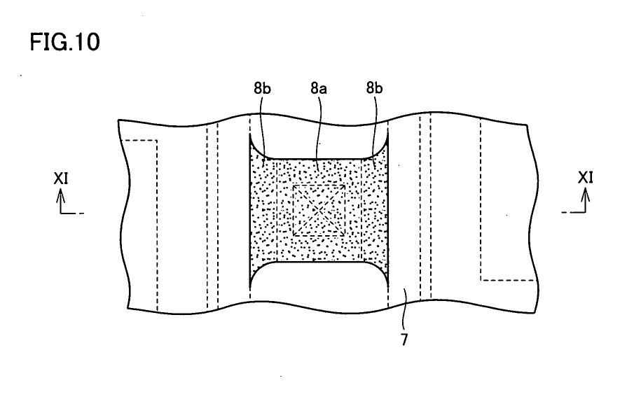

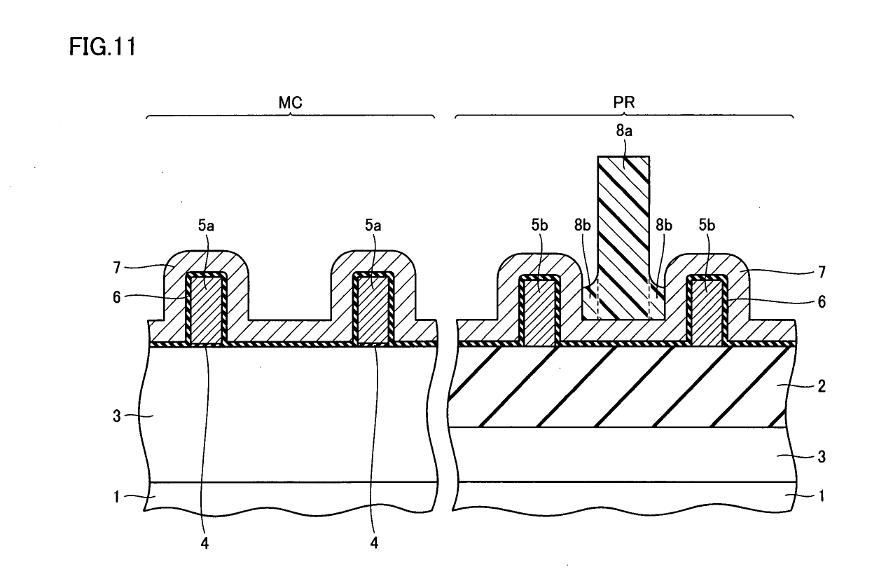

Next, as shown in FIG. 9, using a prescribed mask 51, photoresist 8 is subjected to an exposure process. Here, in peripheral circuit region PR, an exposure process is performed in such a manner that the photoresist is left due to poor resolution at a part A of a gap L between the original resist pattern for forming a pad portion and polysilicon film 7 covering control gate interconnection 5b. Then, a development process is performed on photoresist 8 subjected to the exposure process, resulting in resist patterns 8a, 8b as shown in FIG. 10 and FIG. 11.

Resist pattern 8a is the original resist pattern for forming a pad portion, and resist pattern 8b is a resist pattern left due to poor resolution. The part of polysilicon film 7 that is positioned immediately under resist pattern 8b thus connects the part of polysilicon film 7 that is positioned immediately under resist pattern 8a to the part of polysilicon film 7 that is positioned on the side surface of control gate interconnection 5b.

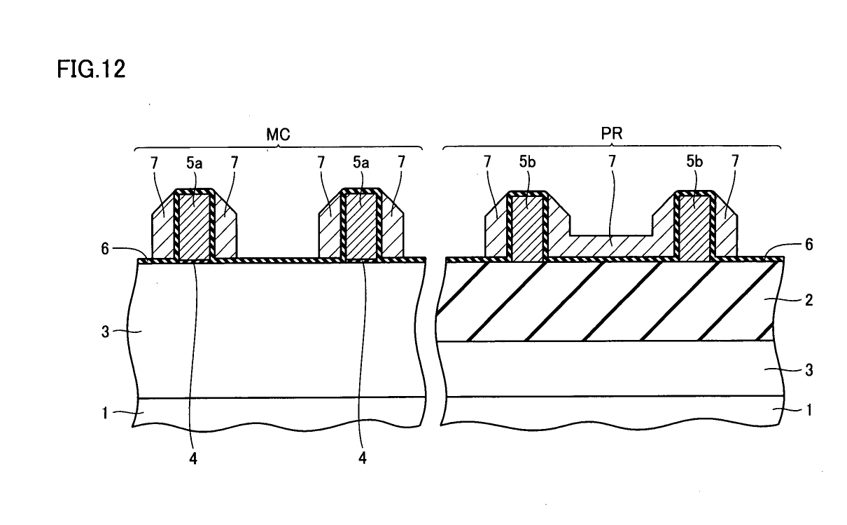

Then, as shown in FIG. 12, using resist patterns 8a, 8b as a mask, anisotropic etching is performed on polysilicon film 7, so that the part of polysilicon film 7 that is positioned on the opposite side surfaces of control gate electrode 5a and the part of polysilicon film 7 that is positioned on the opposite side surfaces of control gate interconnection 5b are left while the part of polysilicon film 7 that is positioned in the other part is removed. Thus, polysilicon film 7 no longer has a part positioned on the upper surfaces of control gate electrode 5a and control gate interconnection 5b. Thereafter, resist patterns 8a, 8b are removed.

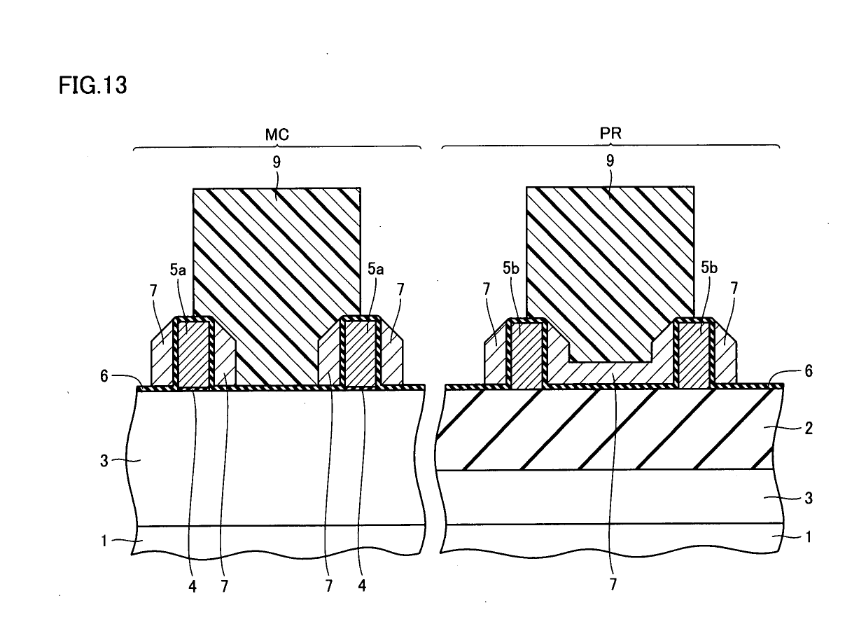

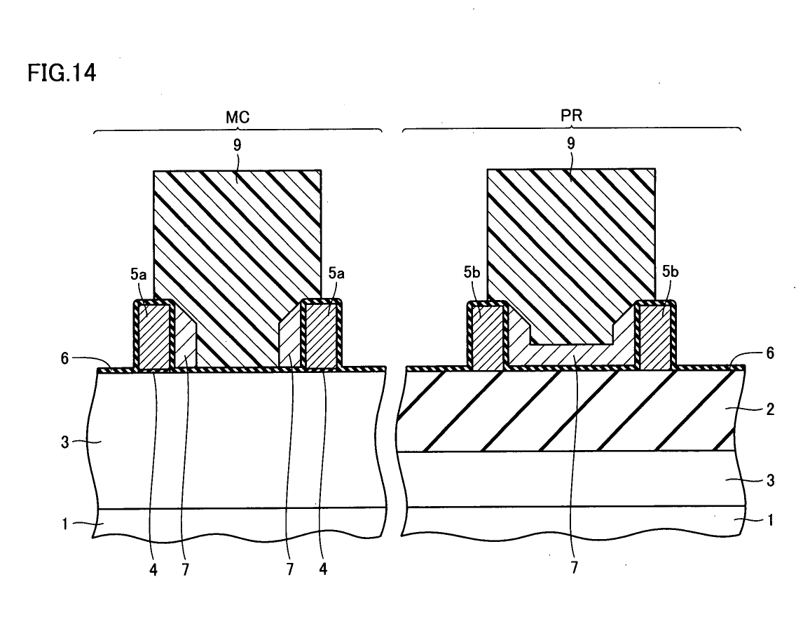

Then, as shown in FIG. 13, a resist pattern 9 is formed to cover the part of polysilicon film 7 that is positioned on the side surfaces opposing to each other in the two control gate electrodes 5a, and a resist pattern 9 is formed to cover the part of polysilicon film 7 that is positioned on the side surfaces opposing to each other in the two control gate interconnections 5b. Using resist pattern 9 as a mask, isotropic etching is performed, so that the part of polysilicon film 7 that is not covered with resist pattern 9 is removed, as shown in FIG. 14.

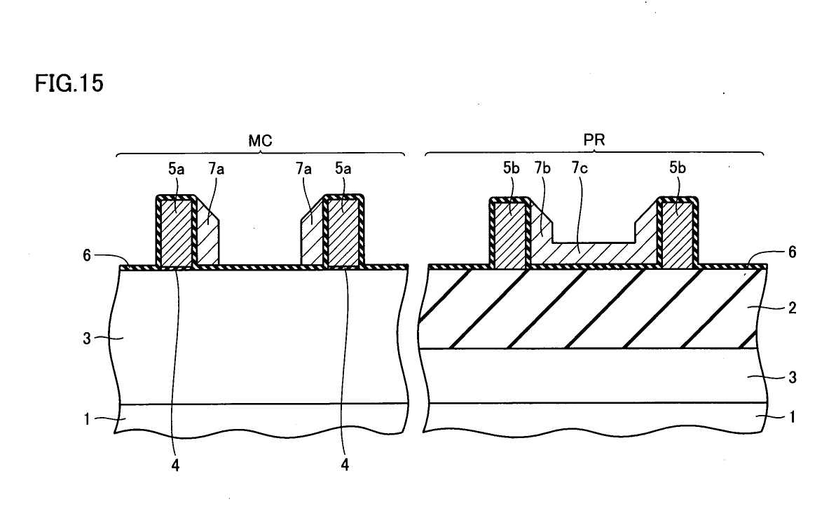

Then, as shown in FIG. 15, resist pattern 9 is removed, so that memory gate electrode 7a is formed on one side surface of control gate electrode 5a in memory cell region MC. Memory gate interconnection 7b connected to memory gate electrode 7a is formed on one side surface of control gate interconnection 5b in peripheral circuit region PR. In addition, pad portion 7c connected to memory gate interconnection 7b is formed.

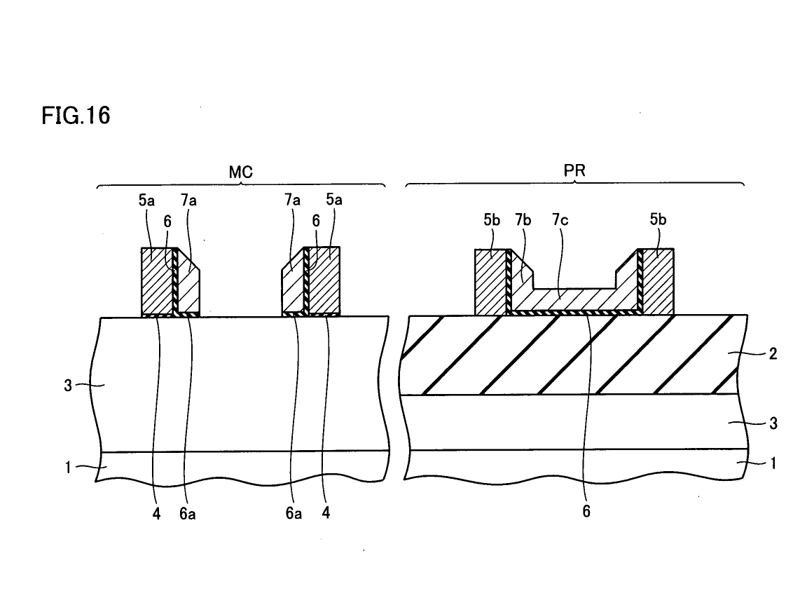

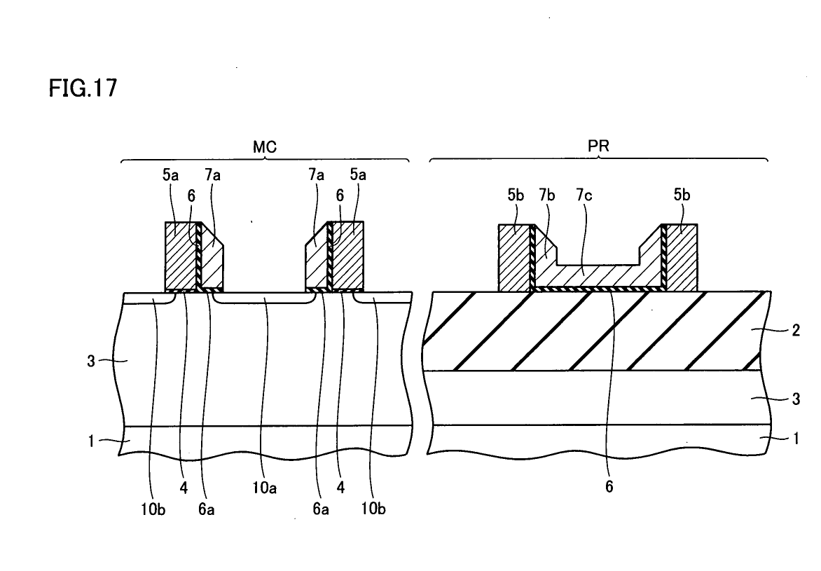

Then, isotropic etching is performed to remove the part of ONO film 6 that is exposed on the surface of semiconductor substrate 1, as shown in FIG. 16. Then, using control gate electrode 5a and memory gate electrode 7a as a mask, impurity ions of a prescribed conductivity type are implanted, so that low concentration impurity region 10a serving as a part of the source region and low concentration impurity region 10b serving as a part of the drain region are formed as shown in FIG. 17.

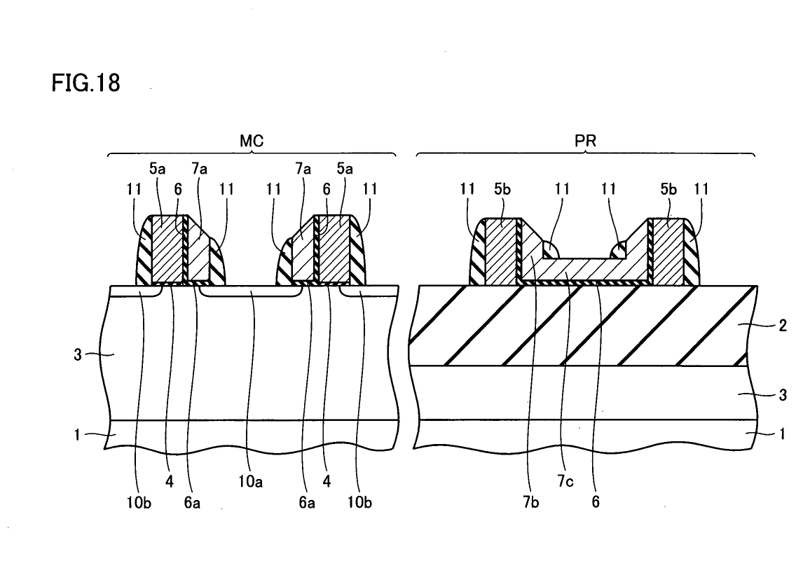

Then, an insulating film (not shown) such as a silicon oxide film is formed, for example, by CVD on semiconductor substrate 1 to cover control gate electrode 5a, memory gate electrode 7a and the like. Anisotropic etching is performed on the insulating film, so that sidewall insulating film 11 is formed on each side surface of control gate electrode 5a and memory gate electrode 7a in memory cell region MC, as shown in FIG. 18. In peripheral circuit region PR, sidewall insulating film 11 is formed on each side surface of control gate interconnection 5b and memory gate interconnection 7b.

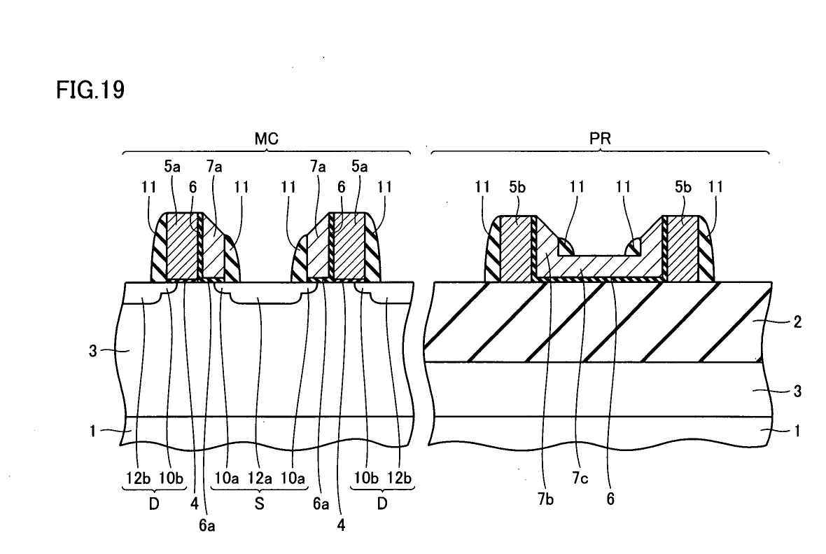

Then, as shown in FIG. 19, using control gate electrode 5a, memory gate electrode 7a and sidewall insulating film 11 as a mask, impurity ions of a prescribed conductivity type are implanted, so that high concentration impurity region 12a serving as a part of the source region and high concentration impurity region 12b serving as a part of the drain region are formed. Thus, source region S formed of low concentration impurity region 10a and high concentration impurity region 12a and drain region D formed of low concentration impurity region 10b and high concentration impurity region 12b are formed.

Then, a prescribed metal film (not shown) of cobalt, nickel, or the like is formed, for example, by sputtering on semiconductor substrate 1 to cover control gate electrode 5a, memory gate electrode 7a and the like. Then, a heat treatment is performed at a prescribed temperature under an atmosphere, for example, of nitrogen, so that in memory cell region MC, silicon in the polysilicon film forming control gate electrode 5a and the like reacts with the metal (silicidation) to form a metal silicide film. Similarly, in peripheral circuit region PR, silicon in the polysilicon film forming control gate interconnection 5b and the like reacts with the metal (silicidation) to form a metal silicide film. Thereafter, the unreacted metal film is removed.

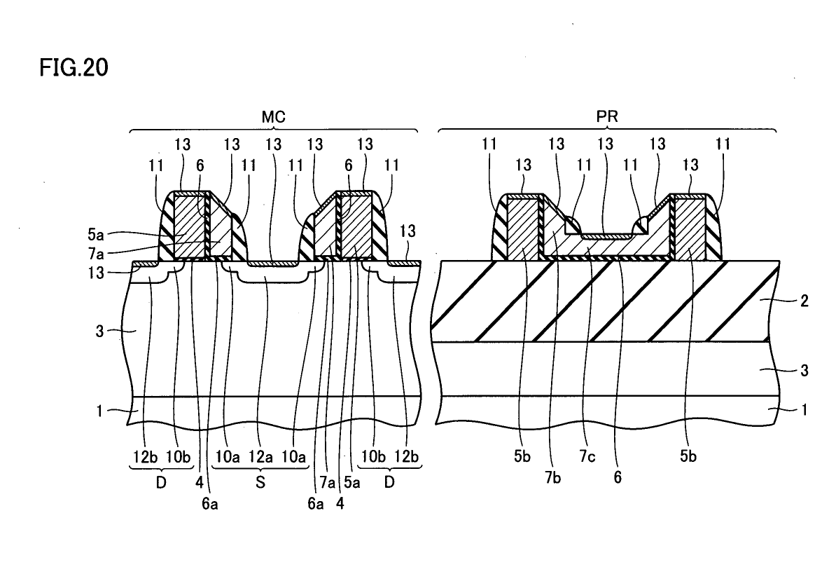

In this manner, as shown in FIG. 20, in memory cell region MC, metal silicide film 13 is formed on each of the surface of control gate electrode 5a and the surface of memory gate electrode 7a. In addition, in peripheral circuit region PR, metal silicide film 13 is formed on each of the surface of control gate interconnection 5b, the surface of memory gate interconnection 7b and the surface of pad portion 7c.

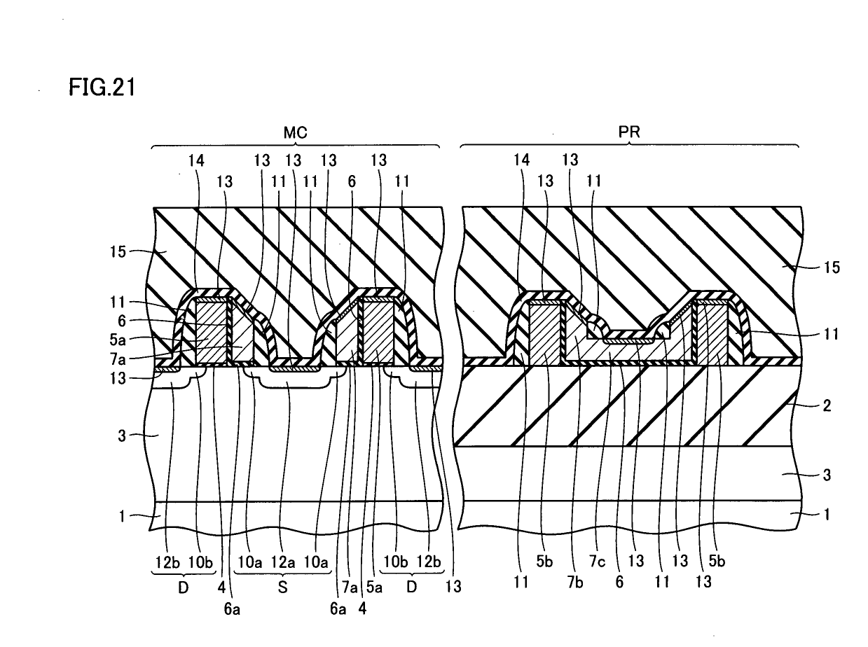

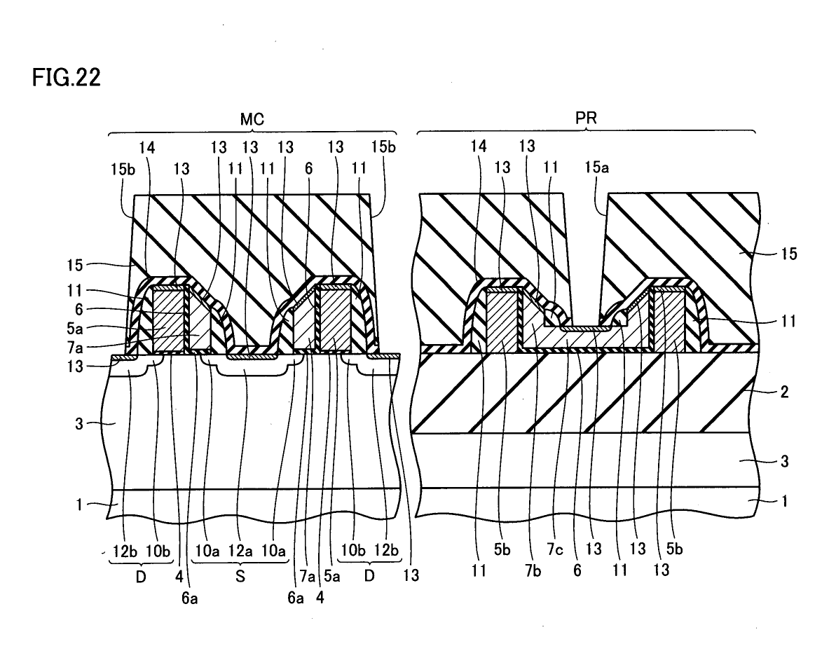

Then, as shown in FIG. 21, silicon nitride film 14 is formed, for example, by CVD on semiconductor substrate 1 to cover control gate electrode 5a, memory gate electrode 7a and the like. Interlayer insulating film 15 having a prescribed thickness such as a silicon oxide film is formed, for example, by CVD on semiconductor substrate 1 to cover silicon nitride film 14. Then, a resist pattern (not shown) for forming a contact hole is formed on interlayer insulating film 15. Using the resist pattern as a mask, anisotropic etching is performed on interlayer insulating film 15, so that in memory cell region MC, contact hole 15b is formed to expose a surface of the drain region, as shown in FIG. 22. In addition, in peripheral circuit region PR, contact hole 15a is formed to expose the surface of pad portion 7c.

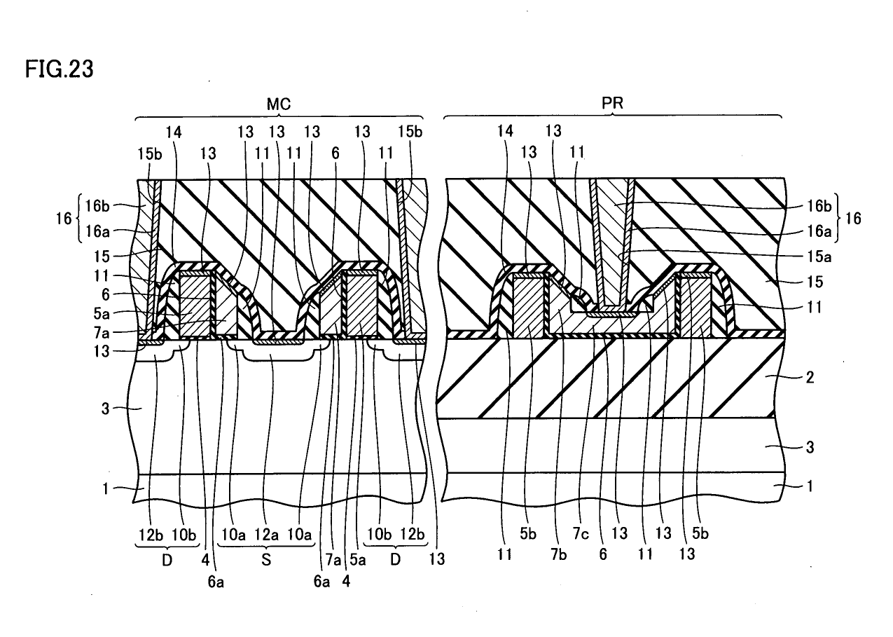

Then, a film (not shown) serving as a contact member formed of prescribed first layer and second layer is formed on the surface of interlayer insulating film 15 to fill in contact holes 15a, 15b. Then, a CMP process is performed on the film, so that the part of the film serving as a contact member that is positioned on the upper surface of interlayer insulating film 15 is removed, thereby forming plug 16 formed of first layer 16a and second layer 16b in contact hole 15b in memory cell region MC, as shown in FIG. 23. Plug 16 formed of first layer 16a and second layer 16b is formed in contact hole 15a in peripheral circuit region PR.

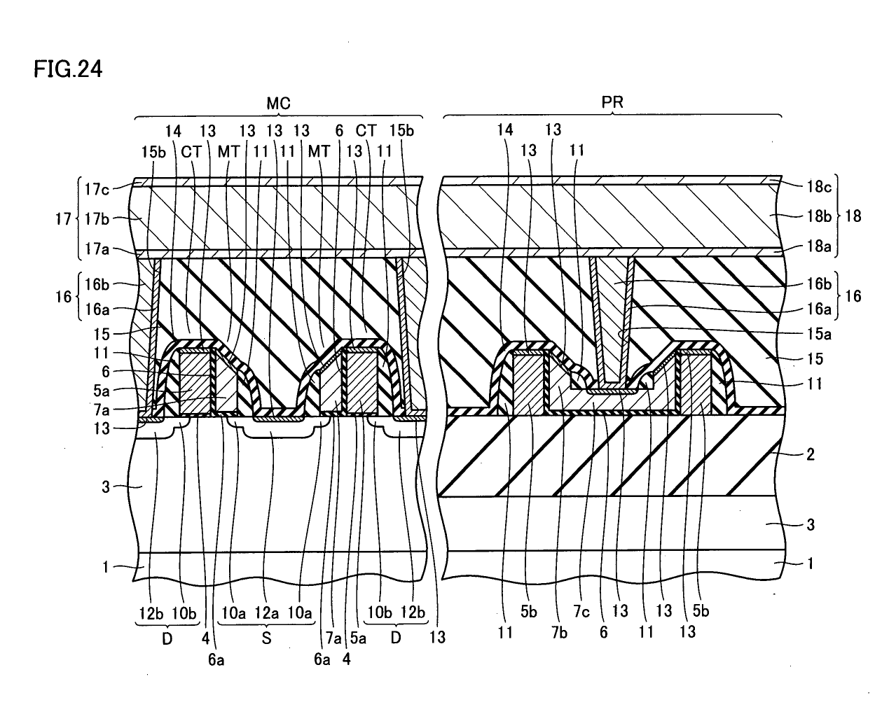

Then, a film (not shown) serving as an interconnection formed of prescribed first layer, second layer and third layer is formed on the surface of interlayer insulating film 15. Then, prescribed processing is performed on the film, so that interconnection 17 formed of first layer 17a, second layer 17b and third layer 17c and connected to plug 16 is formed in memory cell region MC, as shown in FIG. 24. Interconnection 18 formed of first layer 18a, second layer 18b and third layer 18c and connected to plug 16 is formed in peripheral circuit region PR. The main part of the nonvolatile semiconductor memory device is thus completed.

In the nonvolatile semiconductor memory device as described above, polysilicon film 7 forming memory gate interconnection 7b and the like includes a part (a first protrusion portion) formed to extend from the part positioned on one side surface of control gate interconnection 5b to the side opposite to the side where that control gate interconnection 5b is positioned, and that part serves as pad portion 7c. Contact hole 15a is formed to expose that pad portion 7c. Then, a height H2 at the part of the polysilicon film that is positioned on one side surface of control gate interconnection 5b is set to be equal to or lower than a height H1 of control gate interconnection 5b, so that polysilicon film 7 forming memory gate interconnection 7b and the like does not two-dimensionally overlap control gate interconnection 5b. It is noted that two-dimensionally not overlapping means not overlapping in the layout.

In this manner, polysilicon film 7 forming memory gate interconnection 7b and the like does not two-dimensionally overlap control gate interconnection 5b, so that contact hole 15a can be formed accurately with reduced thickness of interlayer insulating film 15 and the process margin can be increased. This point will be detailed below.

First, in the photolithography process in forming a pad portion shown in FIG. 9, a resist pattern is formed using poor resolution. In this photolithography process, a mask pattern and the like are set such that the original resist pattern for forming a pad portion is formed at a prescribed distance away from the part of polysilicon film 7 that covers control gate interconnection 5b so as not to form a resist pattern immediately above the upper surface of polysilicon film 7 covering control gate interconnection 5b. Then, as such a distance (spacing), between the part of polysilicon film 7 that is positioned on the side surface of control gate interconnection 5b and the original resist pattern, poor resolution resulting from that part of polysilicon film 7 is intentionally caused, so that the distance where the photoresist is left between the original resist pattern and that part of the polysilicon film is set.

The distance of gap L for photoresist 8 to be left using such poor resolution is preferably set, for example, at about 70 nm on average. In this case, where the alignment variations in photolithography are about 50 nm, the distance of gap L is about 20 nm at shortest and about 120 nm at longest. Accordingly, as shown in FIG. 10 and FIG. 11, after the development process, a resist pattern is not formed on the upper surface of control gate interconnection 5b while resist pattern 8a is formed at a distance away from the part of polysilicon film 7 that covers control gate interconnection 5b and resist pattern 8b is left due to poor resolution between resist pattern 8a and that part of polysilicon film 7.

Then, using such resist patterns 8a, 8b as a mask, anisotropic etching for forming pad portion 7c is performed on polysilicon film 7, so that the part of polysilicon film 7 that is positioned on the upper surface of control gate interconnection 5b is removed. Thus, polysilicon film 7 forming memory gate interconnection 7b and the like no longer has a part that two-dimensionally overlaps control gate interconnection 5b, and height H2 of the part of polysilicon film 7 that is positioned on the side surface of control gate interconnection 5b becomes substantially equal to or lower than height H1 of control gate interconnection 5b.

Therefore, the thickness required for interlayer insulating film 15 to prevent control gate interconnection 5b and the like from being exposed by the CMP process in forming a plug in interlayer insulating film 15 can be reduced, as compared with the case where polysilicon film 7 has a part two-dimensionally overlapping control gate interconnection 5b, because of the absence of such a part of the polysilicon film.

As a result, the aspect ratio (the depth/the opening diameter) of contact holes 15a, 15b to be formed in interlayer insulating film 15 can be reduced, so that a contact hole with high dimensional accuracy can be opened thereby improving the process margin.

### Second Embodiment

The nonvolatile semiconductor memory device as described above is illustrated as including a pad portion applying a prescribed voltage to adjacent two memory gate interconnections, by way of example. Here, a nonvolatile semiconductor memory device will be illustrated as including, as a modified pad portion, a pad portion applying a prescribed voltage individually to each of adjacent two memory gate interconnections, by way of example.

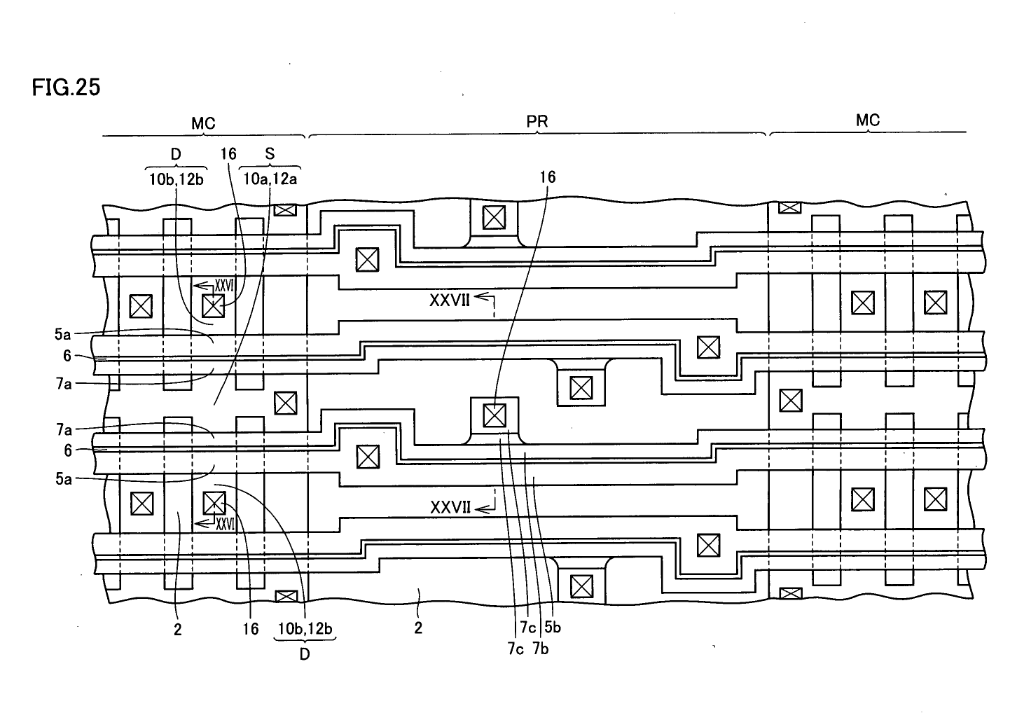

As shown in FIG. 25, a control transistor CT including control gate electrode 5a and a memory transistor MT including memory gate electrode 7a are formed in memory cell region MC partitioned by element isolation insulating film (STI) 2. Control gate interconnection 5b electrically connecting control gate electrodes 5a to each other and memory gate interconnection 7b electrically connecting memory gate electrodes 7a to each other are formed in peripheral circuit region PR. Pad portion 7c electrically connected to each memory gate interconnection 7b is formed in a prescribed region on the surface of element isolation insulating film 2 in peripheral circuit region PR.

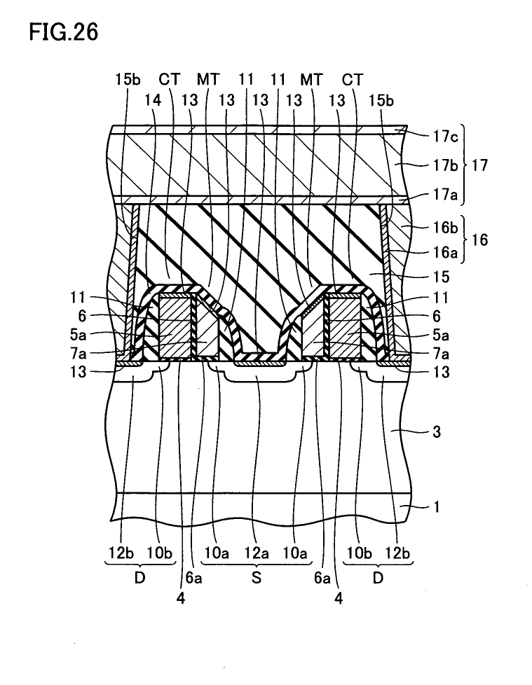

The structure of the memory cell is similar to the structure of the memory cell shown in FIG. 2. As shown in FIG. 26, control gate electrode 5a is formed on the surface of semiconductor substrate 1 with control gate insulating film 4 interposed thereon. Sidewall-like memory gate electrode 7a is formed on one side surface of the opposite side surfaces of control gate electrode 5a. Memory gate electrode 7a is formed on the surface of semiconductor substrate 1 with ONO film 6 interposed. ONO film 6 extends from the surface of semiconductor substrate 1 onto one side surface of control gate electrode 5a to be interposed between the side surface of control gate electrode 5a and memory gate electrode 7a.

Drain region D is formed in a region of semiconductor substrate 1 that is positioned on the side opposite to the side where memory gate electrode 7a is positioned across control gate electrode 5a. On the other hand, source region S is formed in a region of semiconductor substrate 1 that is positioned on the side opposite to the side where control gate electrode 5a is positioned across memory gate electrode 7a.

Metal silicide film 13 is formed on each surface of control gate electrode 5a and the like. Interlayer insulating film 15 is formed on semiconductor substrate 1 with silicon nitride film 14 interposed to cover control gate electrode 5a and memory gate electrode 7a. Plug 16 is formed in contact hole 15b formed in interlayer insulating film 15. Interconnection 17 electrically connected to plug 16 is additionally formed on interlayer insulating film 15.

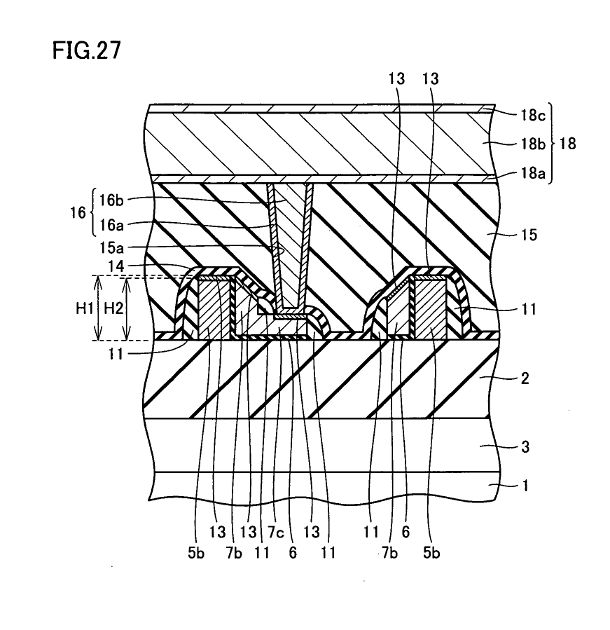

The structure of pad portion 7c and the region in the vicinity thereof will now be described. As shown in FIG. 27, memory gate interconnection 7b is formed with ONO film 6 interposed on each of the side surfaces on the sides opposing to each other in two control gate interconnections 5b formed spaced apart from each other on the surface of element isolation insulating film 2. In the region sandwiched between two memory gate interconnections 7b opposing to each other, pad portion 7c connected only to one memory gate interconnection 7b and a pad portion (not shown) connected only to the other memory gate interconnection 7b are formed. ONO film 6 is interposed between pad portion 7c and element isolation insulating film 2.

Metal silicide film 13 is formed on each surface of control gate interconnection 5b and the like. Interlayer insulating film 15 is formed on semiconductor substrate 1 with silicon nitride film 14 interposed to cover control gate interconnection 5b and memory gate interconnection 7b. Plug 16 is formed in contact hole 15a formed in interlayer insulating film 15. Interconnection 18 electrically connected to plug 16 is additionally formed on interlayer insulating film 15.

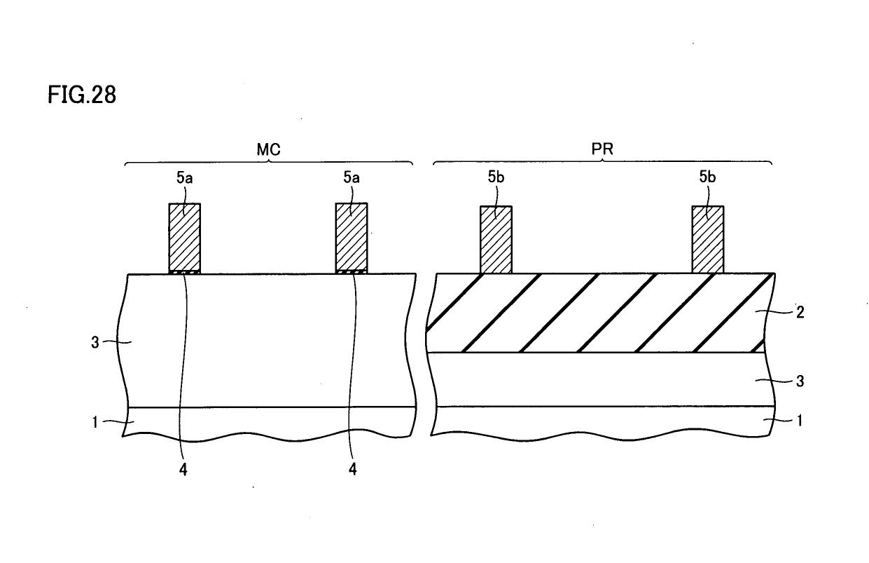

A method of manufacturing the nonvolatile semiconductor memory device as described above will now be described. First, through the step similar to the step shown in FIG. 7 as described above, as shown in FIG. 28, control gate electrode 5a is formed on the surface of semiconductor substrate 1 with control gate insulating film 4 interposed in memory cell region MC. Control gate interconnection 5b connected to control gate electrode 5a is formed in peripheral circuit region PR.

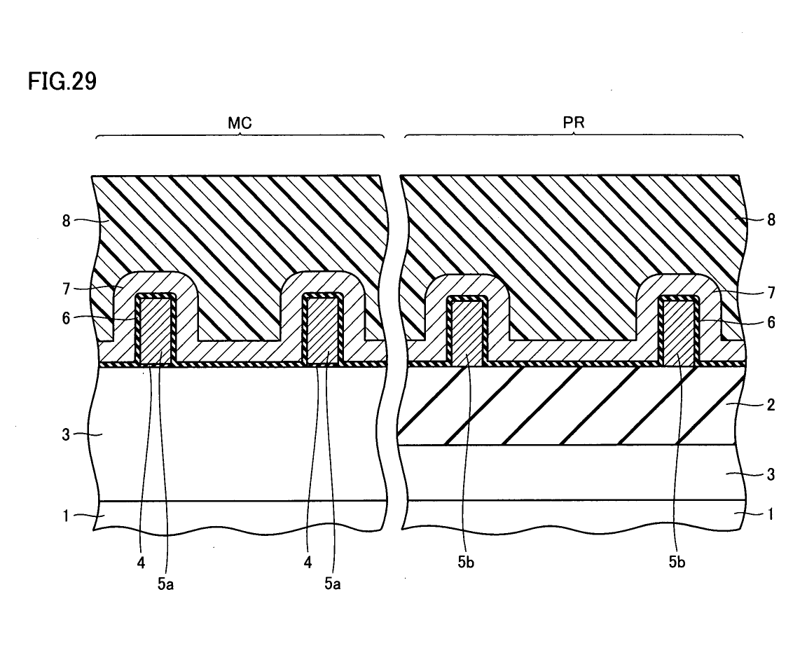

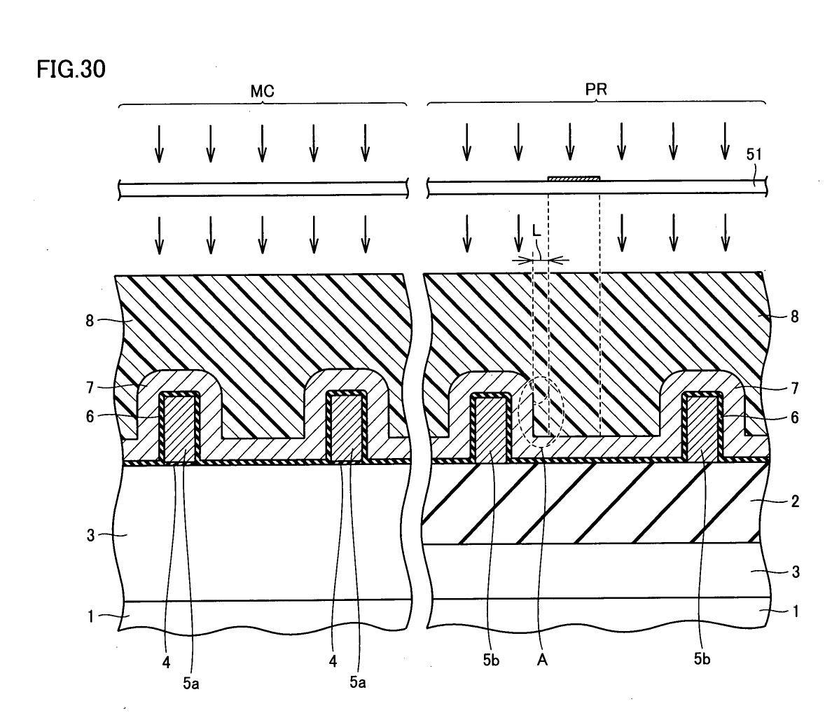

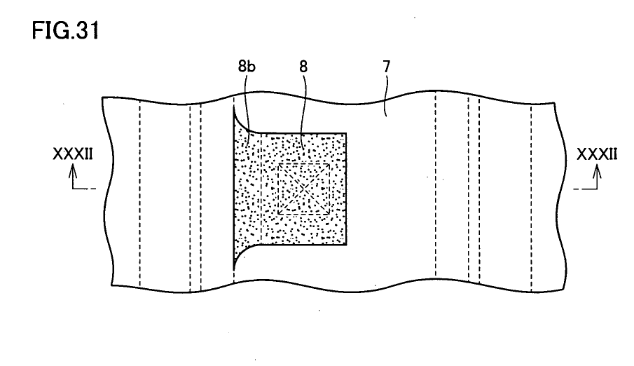

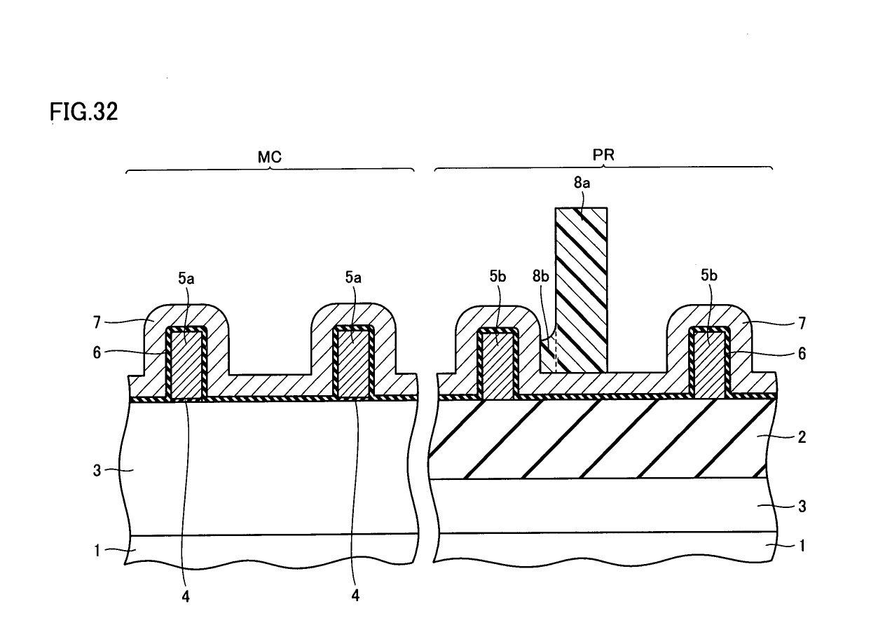

Next, through the step similar to the step shown in FIG. 8 as described above, as shown in FIG. 29, photoresist 8 for forming a pad portion is coated on polysilicon film 7. Then, as shown in FIG. 30, an exposure process is performed on photoresist 8 using prescribed mask 51, Here, in peripheral circuit region PR, an exposure process is performed in such a manner that the photoresist is left due to poor resolution at part A of gap L between the original resist pattern for forming a pad portion and that part of polysilicon film 7 which covers one control gate interconnection 5b of adjacent two control gate interconnections 5b. Then, a development process is performed on photoresist 8 subjected to the exposure process, resulting in resist patterns 8a, 8b, as shown in FIG. 31 and FIG. 32.

Resist pattern 8a is the original resist pattern for forming a pad portion, and resist pattern 8b is a resist pattern left due to poor resolution. The part of polysilicon film 7 that is positioned immediately under resist pattern 8b thus connects the part of polysilicon film 7 that is positioned immediately under resist pattern 8a to the part of polysilicon film 7 that is positioned on the side surface of control gate interconnection 5b.

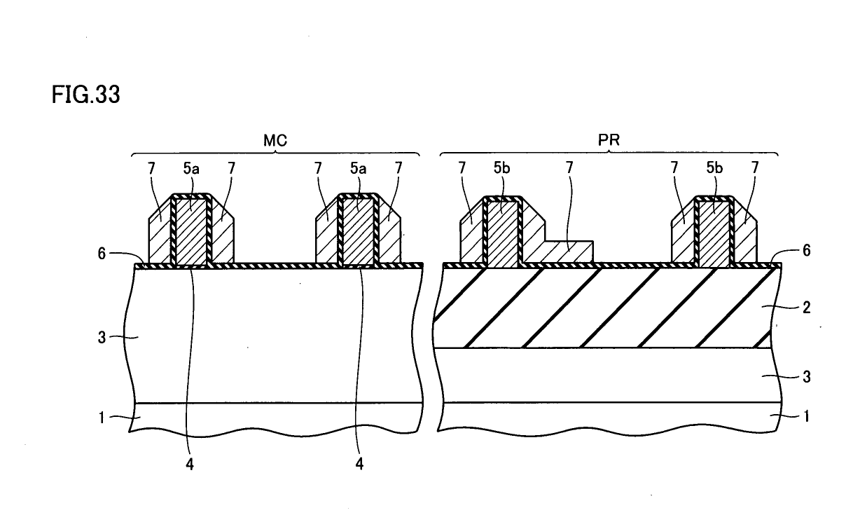

Then, as shown in FIG. 33, using resist patterns 8a, 8b as a mask, anisotropic etching is performed on polysilicon film 7, so that the part of polysilicon film 7 that is positioned on the opposite side surfaces of control gate electrode 5a and the part of polysilicon film 7 that is positioned on the opposite side surfaces of control gate interconnection 5b are left while the part of polysilicon film 7 that is positioned in the other part is removed. Thus, polysilicon film 7 no longer has a part positioned on the upper surfaces of control gate electrode 5a and control gate interconnection 5b. Thereafter, resist patterns 8a, 8b are removed.

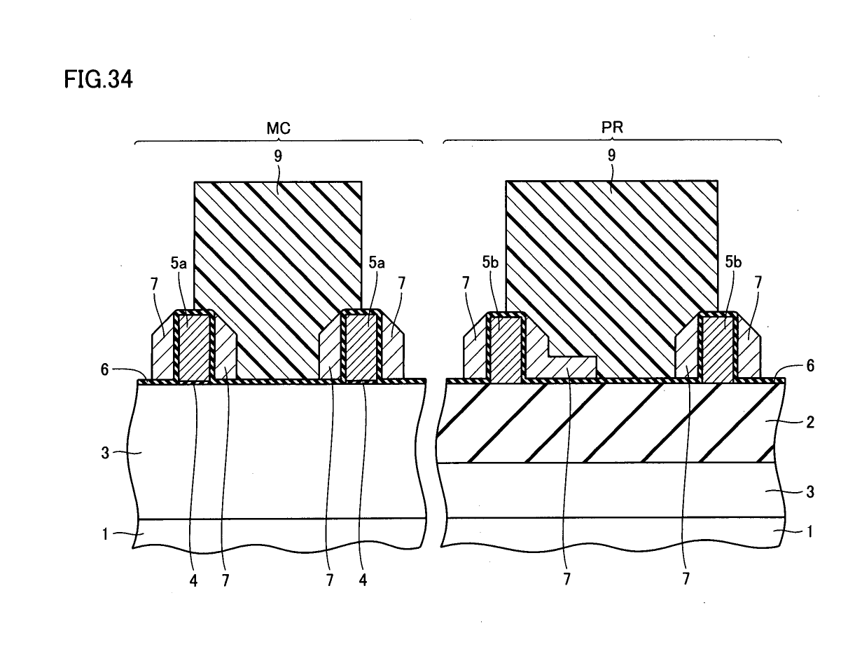

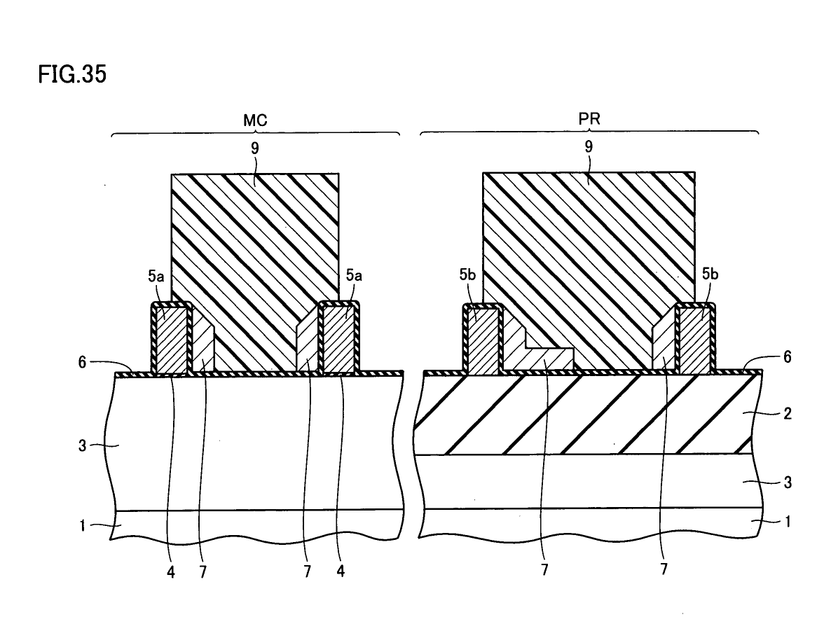

Then, as shown in FIG. 34, resist pattern 9 is formed to cover the part of polysilicon film 7 that is positioned on the side surfaces opposing to each other in two control gate electrodes 5a, and resist pattern 9 is formed to cover the part of polysilicon film 7 that is positioned on the side surfaces opposing to each other in two control gate interconnections 5b. Isotropic etching is performed using resist pattern 9 as a mask, so that the part of polysilicon film 7 that is not covered with resist pattern 9 is removed, as shown in FIG. 35.

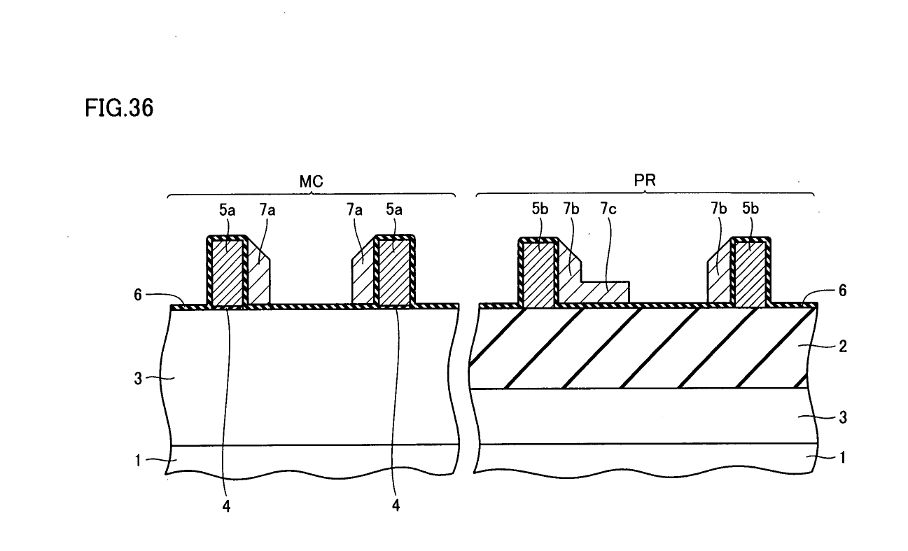

Then, as shown in FIG. 36, resist pattern 9 is removed, so that memory gate electrode 7a is formed on one side surface of control gate electrode 5a, in memory cell region MC. Memory gate interconnection 7b connected to memory gate electrode 7a is formed on each of the side surfaces opposing to each other in adjacent two control gate interconnections 5b, in peripheral circuit region PR. In addition, pad portion 7c connected one memory gate interconnection 7b of these memory gate interconnections 7b is formed.

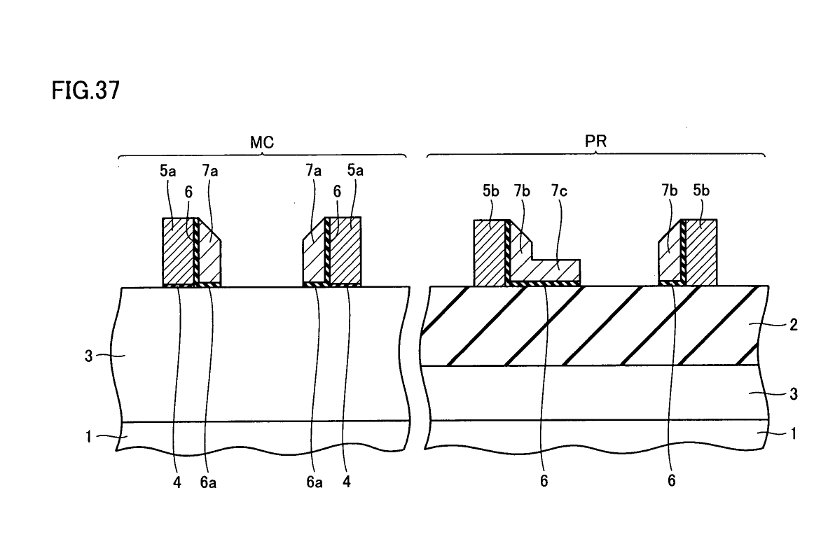

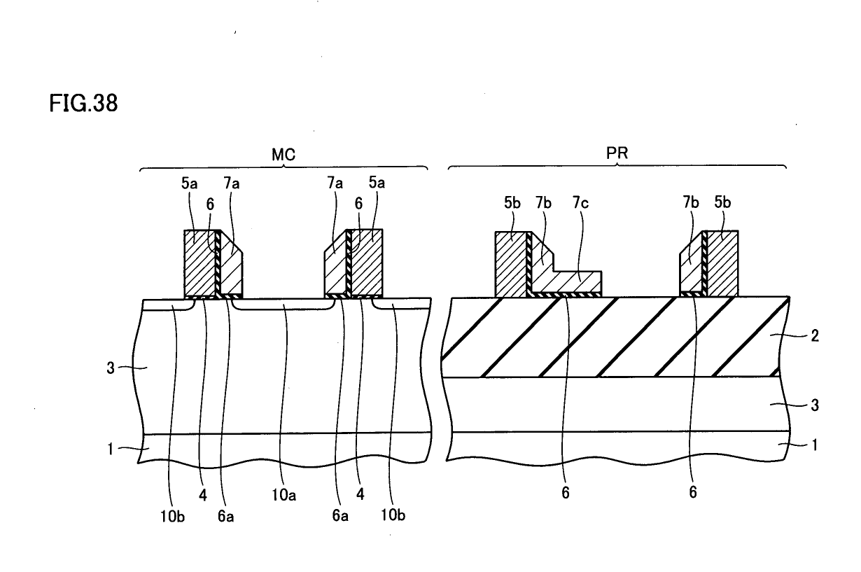

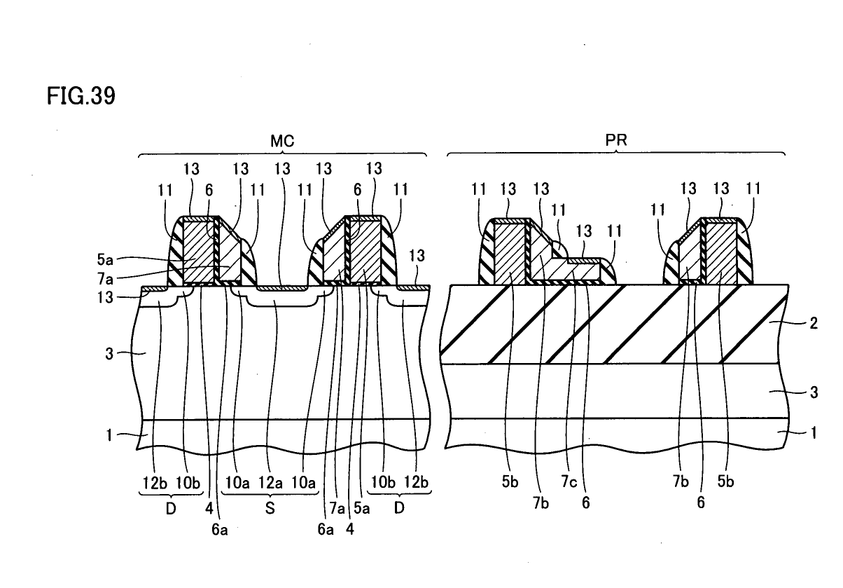

Then, through the step similar to the step shown in FIG. 16, the part of ONO film 16 that is exposed on the surface of semiconductor substrate 1 is removed, as shown in FIG. 37. Then, through the step similar to the step shown in FIG. 17, low concentration impurity region 10a serving as a part of the source region and low concentration impurity region 10b serving as a part of the drain region are formed, as shown in FIG. 38. Then, through the steps similar to the steps shown in FIG. 18 and FIG. 19, source region S formed of low concentration impurity region 10a and high concentration impurity region 12a and drain region D formed of low concentration impurity region 10b and high concentration impurity region 12b are formed, as shown in FIG. 39.

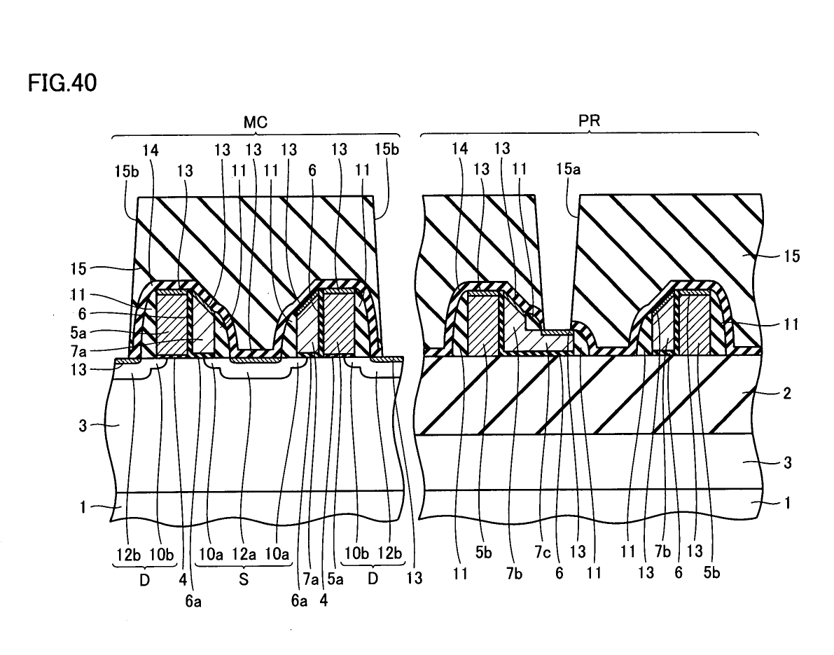

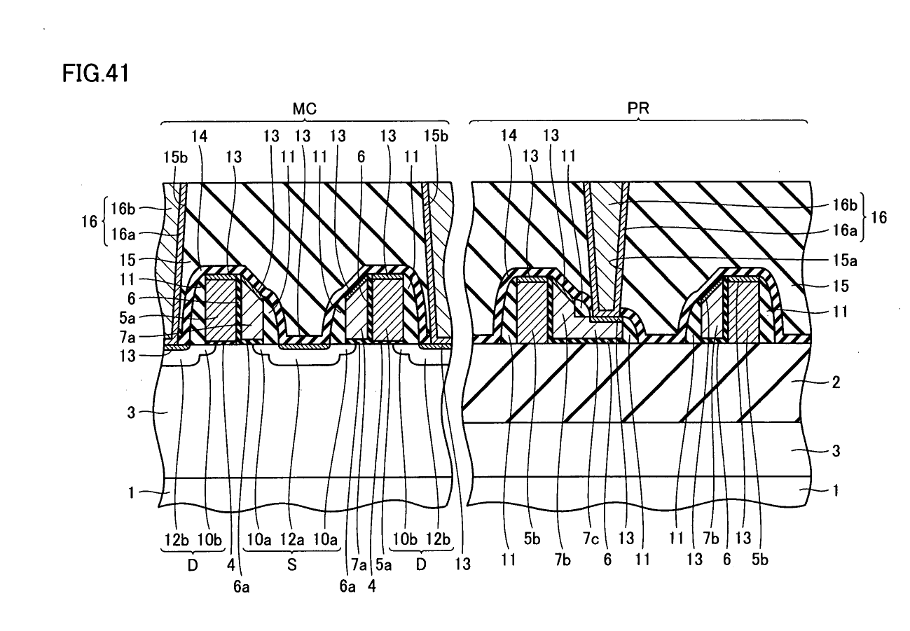

Then, through the steps similar to the steps shown in FIG. 20-FIG. 22, as shown in FIG. 40, contact hole 15b is formed to expose the surface of drain region D in memory cell region MC and contact hole 15a is formed to expose the surface of pad portion 7c in peripheral circuit region PR. Then, through the step similar to the step shown in FIG. 23, as shown in FIG. 41, plug 16 formed of first layer 16a and second layer 16b is formed in contact hole 15b in memory cell region MC, and plug 16 formed of first layer 16a and second layer 16b is formed in contact hole 15a in peripheral circuit region PR.

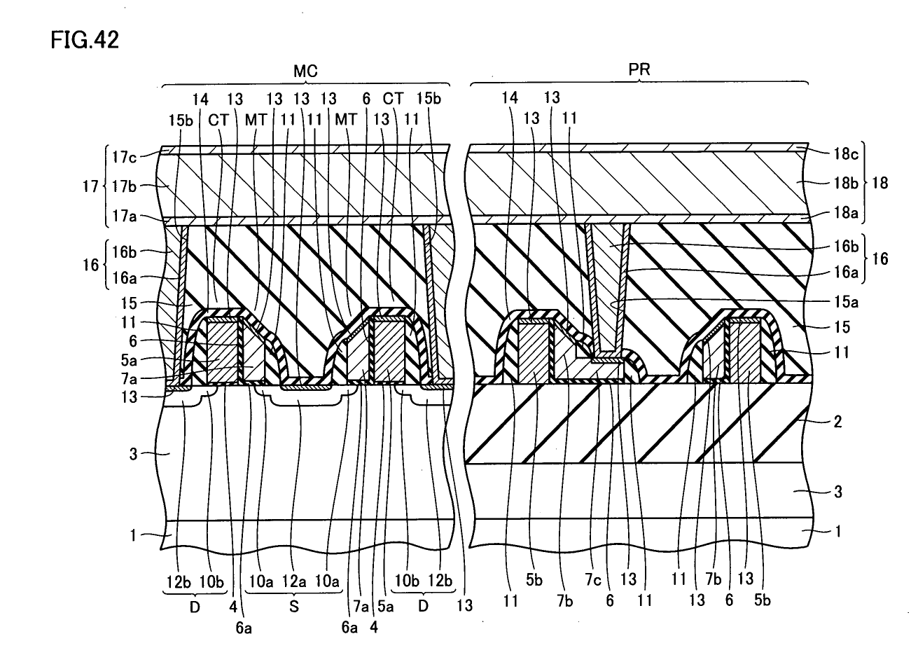

Then, through the step similar to the step shown in FIG. 24, as shown in FIG. 42, interconnection 17 connected to plug 16 is formed in memory cell region MC and interconnection 18 connected to plug 16 is formed in peripheral circuit region PR. The main part of the nonvolatile semiconductor memory device is thus completed.

In the nonvolatile semiconductor memory device as described above, similar to the foregoing one, a resist pattern is formed using poor resolution in the photolithography process in forming a pad portion shown in FIG. 30. In this photolithography process, a mask pattern is set such that a resist pattern is not formed immediately above the upper surface of one control gate interconnection 5b of adjacent two control gate interconnections 5b, and between the part of polysilicon film 7 that is positioned on the side surface of control gate interconnection 5b and the original resist pattern, poor resolution resulting from that part of polysilicon film 7 is intentionally caused to set a distance where the photoresist is left between the original resist pattern and that part of the polysilicon film 7.

In this way, as shown in FIG. 31 and FIG. 32, after the development process, a resist pattern is not formed on the upper surface of control gate interconnection 5b while resist pattern 8a is formed at a distance away from the part of polysilicon film 7 that covers control gate interconnection 5b and resist pattern 8b is left due to poor resolution between resist pattern 8a and that part of polysilicon film 7.

Using such resist patterns 8a, 8b as a mask, anisotropic etching for forming pad portion 7c is performed on polysilicon film 7 to remove the part of polysilicon film 7 that is positioned on the upper surface of control gate interconnection 5b, so that polysilicon film 7 forming memory gate interconnection 7b and the like no longer has a part that two-dimensionally overlaps control gate interconnection 5b. Then, height H2 at the part of polysilicon film 7 that is positioned on the side surface of control gate interconnection 5b becomes substantially equal to or lower than height H1 of control gate interconnection 5b.

Therefore, the thickness required for interlayer insulating film 15 to prevent control gate interconnection 5b and the like from being exposed by the CMP process in forming a plug in interlayer insulating film 15 can be reduced, as compared with the case where polysilicon film 7 has a part two-dimensionally overlapping control gate interconnection 5b, because of the absence of such a part of the polysilicon film.

As a result, the aspect ratio (the depth/the opening diameter) of contact holes 15a, 15b to be formed in interlayer insulating film 15 can be reduced, so that a contact hole with high dimensional accuracy can be opened thereby improving the process margin.

### Third Embodiment

Here, a nonvolatile semiconductor memory device will be described as including, as a modified pad portion, a pad portion in such a manner that the pad portion is partially surrounded by a part of a control gate interconnection, by way of example.

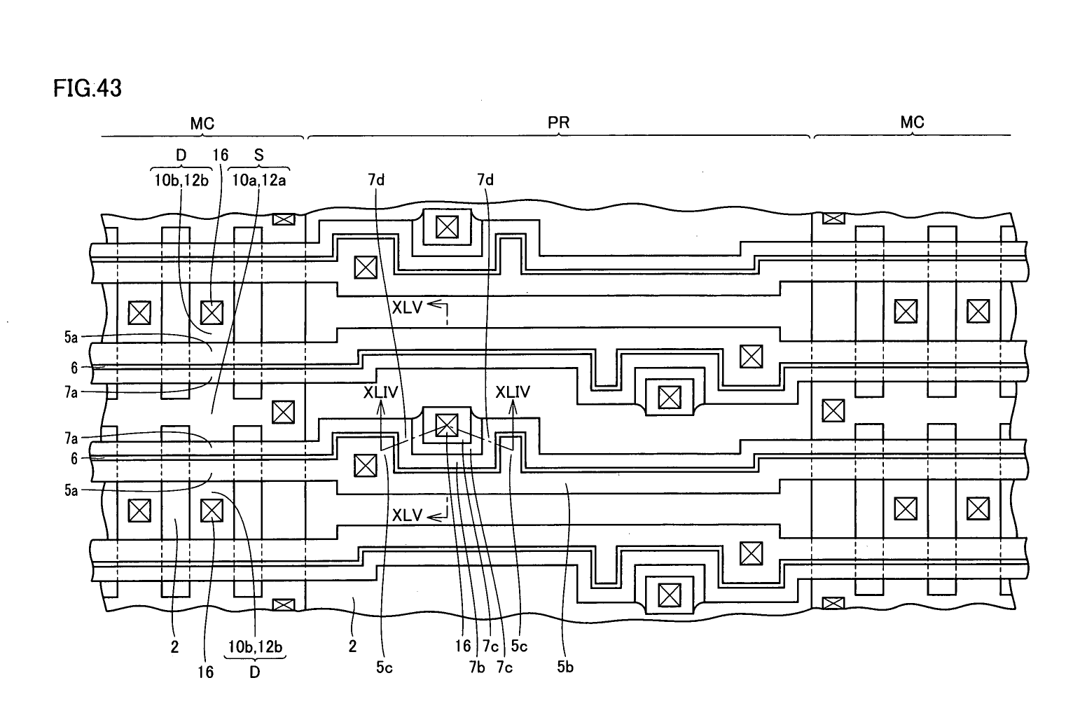

As shown in FIG. 43, a control transistor CT including control gate electrode 5a and a memory transistor MT including memory gate electrode 7a are formed in memory cell region MC partitioned by element isolation insulating film (STI) 2. Control gate interconnection 5b electrically connecting control gate electrodes 5a to each other and memory gate interconnection 7b electrically connecting memory gate electrodes 7a to each other are formed in peripheral circuit region PR. Pad portion 7c connected to memory gate interconnection 7b is formed in a prescribed region on a surface of the element isolation insulating film in peripheral circuit region PR.

Polysilicon film 7 forming memory gate interconnection 7b includes a first portion (a second protrusion portion) 7d protruding to the side opposite to the side where control gate interconnection 5b is positioned and a second portion (a third protrusion portion) 7d formed to be opposed to the first portion 7d at a distance in the direction in which memory gate interconnection 7b extends. Pad portion 7c is formed in a region sandwiched between first portion 7d and second portion 7d. Furthermore, control gate interconnection 5b includes a protrusion portion 5c positioned with ONO film 6 interposed between itself and first portion 7d and a protrusion portion 5c positioned with the ONO film interposed between itself and second portion 7d.

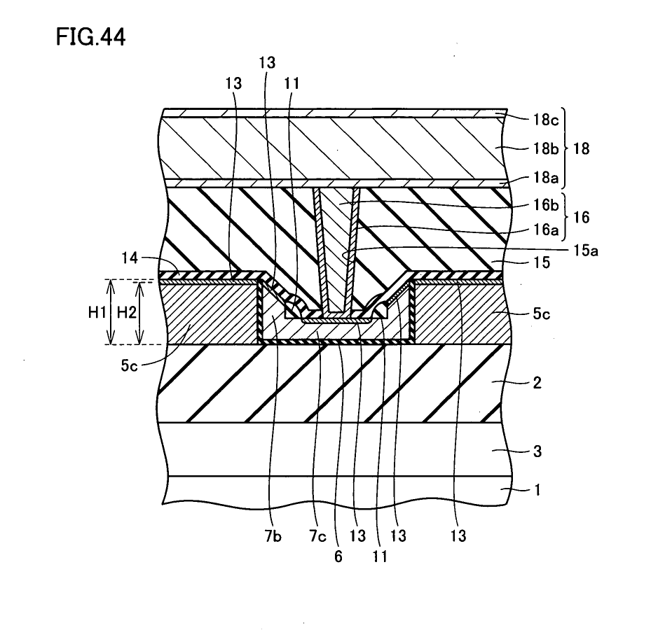

Now, as the structure of pad portion 7c and the region in the vicinity thereof, the structure in cross section taken approximately along one direction (X direction) will be described first. As shown in FIG. 44, first portion 7d and second portion 7d in memory gate interconnection 7b are positioned on the side surfaces opposing to each other in two protrusion portions 5c of control gate interconnection 5b with ONO film 6 interposed. Pad portion 7c is formed in the region of semiconductor substrate 1 that is sandwiched between first portion 7d and second portion 7d.

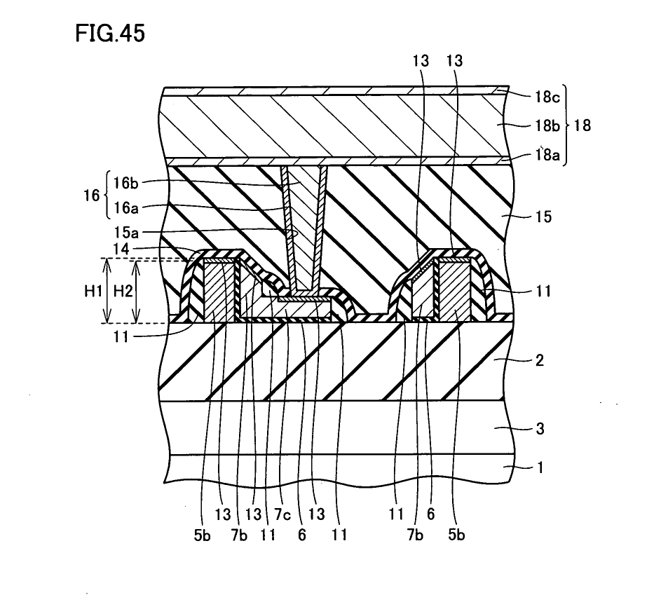

Next, the structure in cross section taken along the direction (Y direction) orthogonal to the one direction will be described. This cross sectional structure is substantially equal to the cross sectional structure shown in FIG. 27. As shown in FIG. 45, memory gate interconnection 7b is formed with ONO film 6 interposed on each of the side surfaces on the sides opposing to each other in two control gate electrodes 5b formed spaced apart from each other on the surface of element isolation insulating film 2. Pad portion 7c connected only to one memory gate interconnection 7b is formed in the region sandwiched between two memory gate interconnections 7b opposing to each other. ONO film 6 is interposed between pad portion 7c and element isolation insulating film 2.

As shown in FIG. 44 and FIG. 45, metal silicide film 13 is formed on each surface of control gate interconnection 5b and the like. Interlayer insulating film 15 is formed on semiconductor substrate 1 with silicon nitride film 14 interposed to cover control gate interconnection 5b and memory gate interconnection 7b. Plug 16 is formed in contact hole 15a formed in interlayer insulating film 15. Interconnection 18 electrically connected to plug 16 is additionally formed on interlayer insulating film 15. It is noted that the structure of the memory cell is similar to the one shown in FIG. 2 and FIG. 26 as described above, and therefore description thereof will not be repeated.

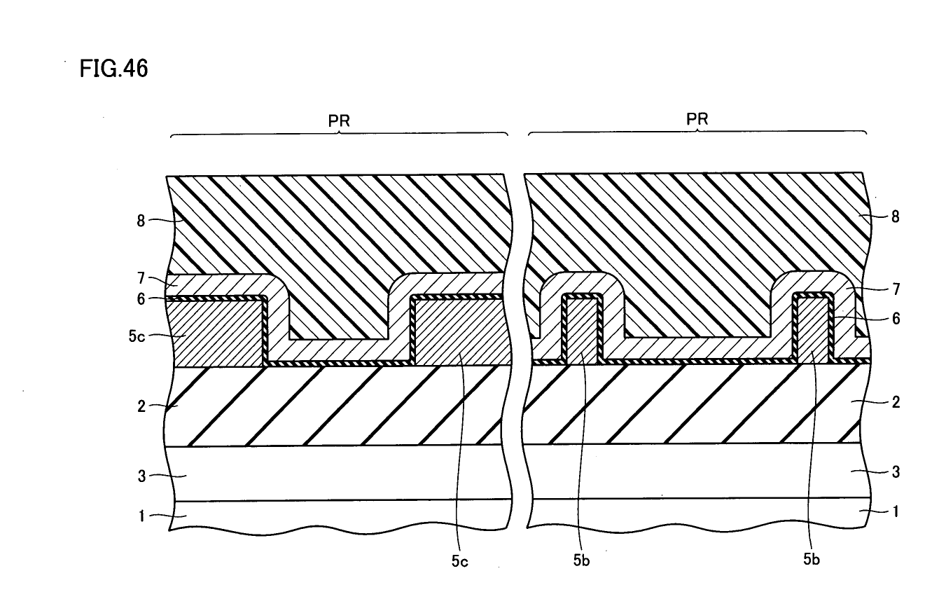

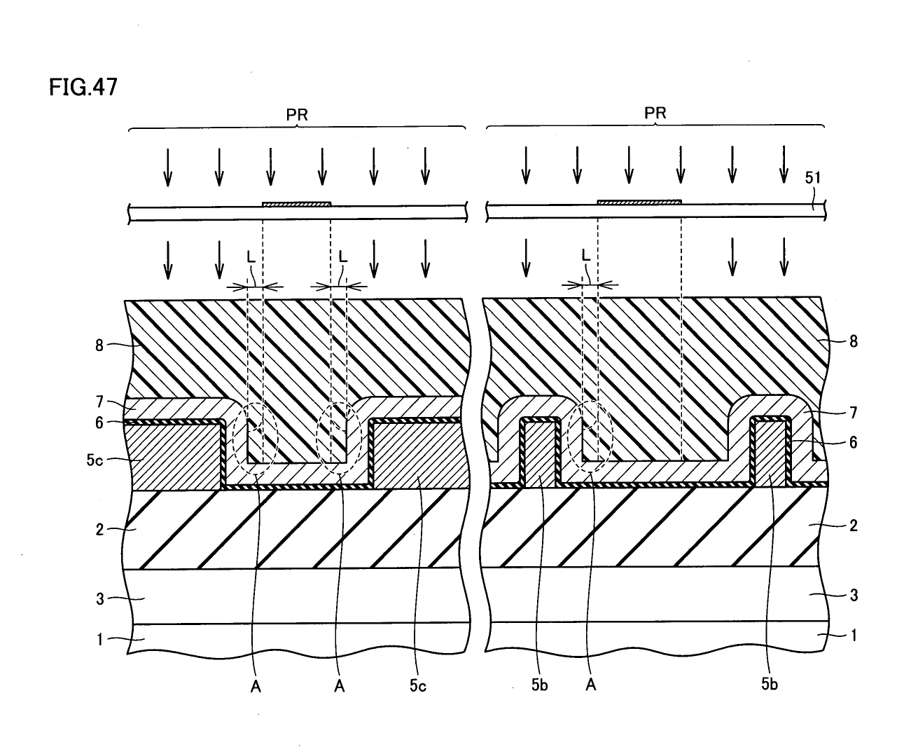

A method of manufacturing the nonvolatile semiconductor memory device as described above will now be described with reference to a cross sectional step view of peripheral circuit region PR. It is noted that the steps for the memory cell portion are similar to the foregoing steps, and therefore description thereof will not be repeated. First, through the steps similar to the steps shown in FIG. 7 and FIG. 8 as described above, as shown in FIG. 46, photoresist 8 for forming a pad portion is coated on polysilicon film 7. Then, as shown in FIG. 47, an exposure process is performed on photoresist 8 using prescribed mask 51.

Here, in the one direction, the exposure process is performed in such a manner that the photoresist is left due to poor resolution at part A of gap L between the original resist pattern for forming a pad portion and the part of polysilicon film 7 that covers each of two protrusion portions 5c opposing to each other in control gate interconnection 5b. On the other hand, in the other direction orthogonal to the one direction, the exposure process is performed in such a manner that the photoresist is left due to poor resolution at part A of gap L between the original resist pattern and the part of polysilicon film 7 that covers one control gate interconnection 5b of adjacent two control gate interconnections 5b.

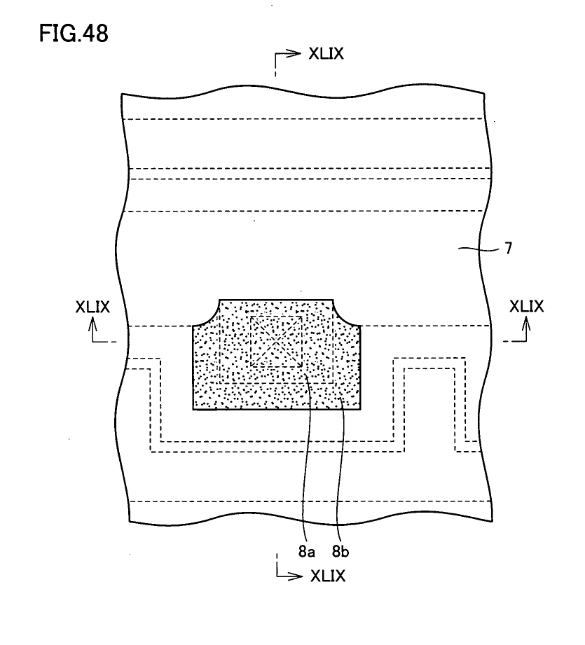

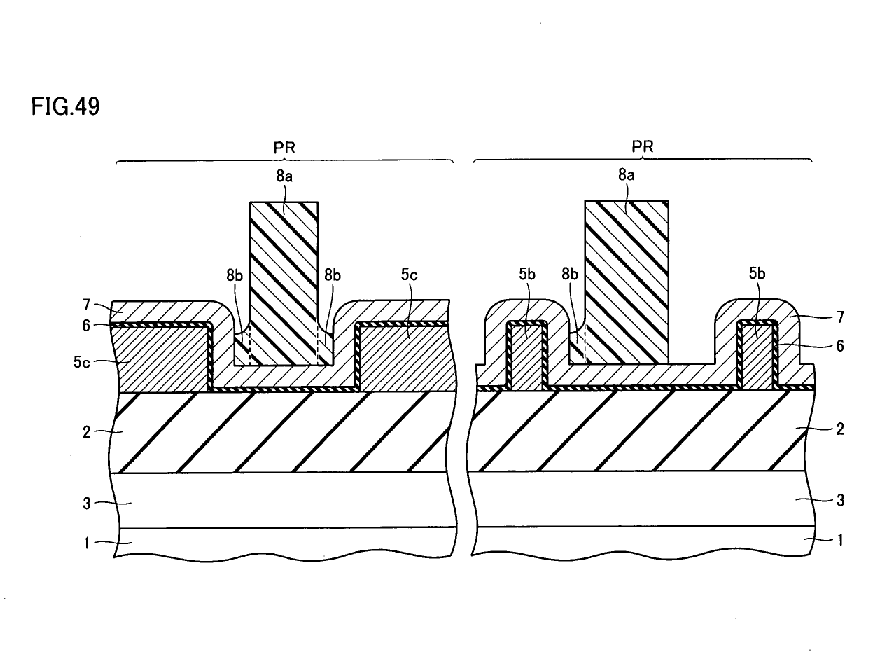

Then, a development process is performed on photoresist 8 subjected to the exposure process, resulting in resist patterns 8a, 8b, as shown in FIG. 48 and FIG. 49. Resist pattern 8a is the original resist pattern for forming a pad portion, and resist pattern 8b is a resist pattern left due to poor resolution. The part of polysilicon film 7 that is positioned immediately under resist pattern 8b thus connects the part of polysilicon film 7 that is positioned immediately under resist pattern 8a to the part of polysilicon film 7 that is positioned on the side surface of control gate interconnection 5b.

Then, anisotropic etching is performed on polysilicon film 7 using resist patterns 8a, 8b as a mask, and in addition, through the steps similar to the steps shown in FIG. 12-FIG. 15 as described above, memory gate interconnection 7b is formed on one side surface of the part extending in the one direction in control gate interconnection 5b, and first portion 7d and second portion 7d of memory gate interconnection 7b are formed on the respective side surfaces opposing to each other in two protrusion portions 5c of the control gate interconnection. In addition, pad portion 7c connected to second portion 7d is formed in a region of the semiconductor substrate that is partially surrounded by memory gate interconnection 7b, first portion 7d and second portion 7d (see FIG. 43).

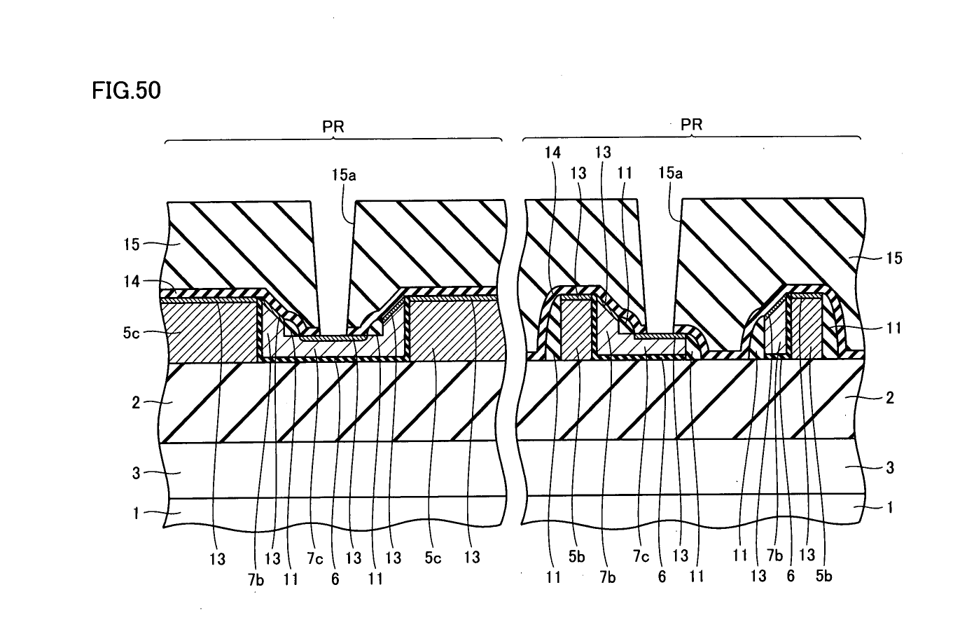

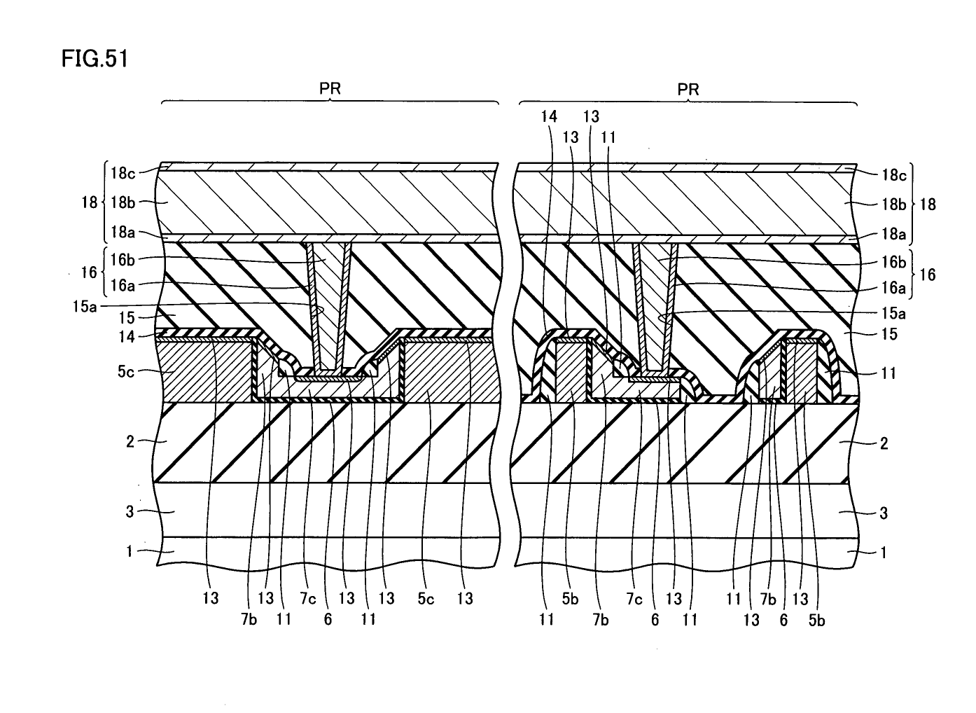

Then, through the steps similar to the steps shown in FIG. 16-FIG. 22 as described above, as shown in FIG. 50, contact hole 15a is formed to expose the surface of pad portion 7c. Then, through the steps similar to the steps shown in FIG. 23 and FIG. 24, as shown in FIG. 51, plug 16 is formed in contact hole 15a, and interconnection 18 electrically connected to plug 16 is formed. The main part of the nonvolatile semiconductor memory device is thus completed.

The nonvolatile semiconductor memory device as described above achieves the following effect in addition to the foregoing effects. More specifically, in the photolithography process (see FIG. 47) using poor resolution to form a resist pattern in forming a pad portion, even if the resist pattern shifted in the Y direction results in that the part of polysilicon film 7 forming the memory gate interconnection extending in the X direction fails to be joined to the part of polysilicon film 7 that forms the pad portion, pad portion 7c is joined to first portion 7d or second portion 7d of the memory gate interconnection which protrudes in the Y direction, thereby achieving the electrical connection.

In addition, since first portion 7d and second portion 7d in such a memory gate interconnection are formed to be opposed to and spaced apart from each other, even if the resist pattern shifted in the X direction results in that the portion of polysilicon film 7 that forms the pad portion fails to be joined to the part of polysilicon film 7 that forms one of first portion 7d and second portion 7d, the part of polysilicon film 7 that forms the pad portion is joined to the part of polysilicon film 7 that forms the other one of first portion 7d and second portion 7d, thereby achieving the electrical connection. Accordingly, the margin can be increased for alignment shift in the photolithography process.

### Fourth Embodiment

Here, a nonvolatile semiconductor memory device will be described as including a pad portion, as another modified pad portion, in such a manner that the pad portion is sandwiched between the end portion of one control gate interconnection and the end portion of the other control gate interconnection, by way of example.

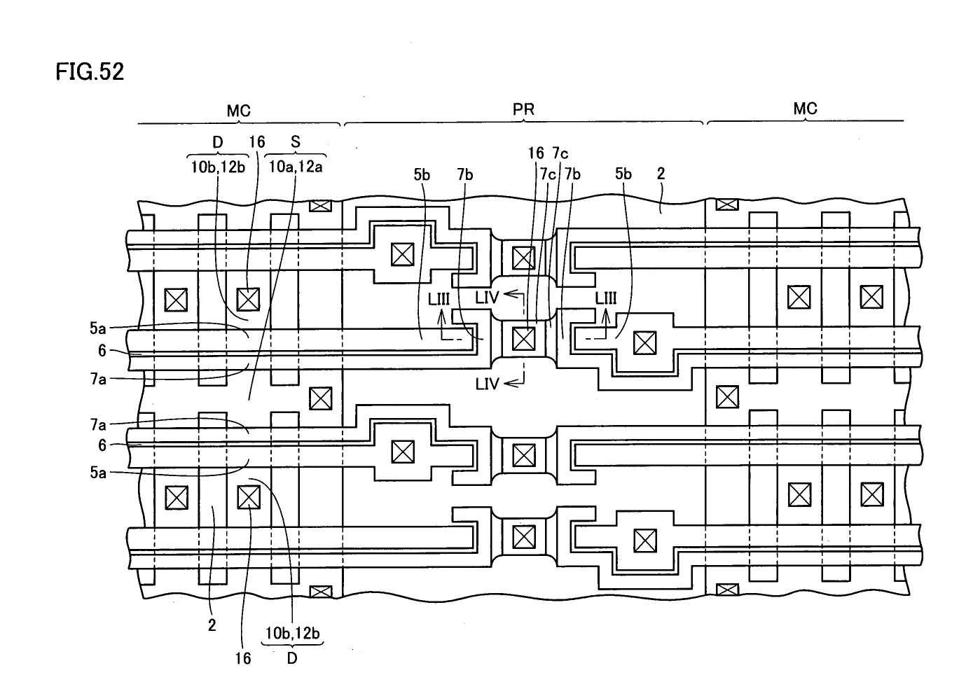

As shown in FIG. 52, a control transistor CT including control gate electrode 5a and a memory transistor MT including memory gate electrode 7a are formed in memory cell region MC partitioned by element isolation insulating film (STI) 2. Control gate interconnection 5b electrically connecting control gate electrodes 5a to each other and memory gate interconnection 7b electrically connecting memory gate electrodes 7a to each other are formed in peripheral circuit region PR. A part (end portion) of one memory gate interconnection 7b and a part (end portion) of the other memory gate interconnection 7b are positioned spaced apart from each other in a prescribed region on the surface of element isolation insulating film 2 in peripheral circuit region PR. These two end portions correspond to a pair of opposing portions. Pad portion 7c connected to each of one memory gate interconnection 7b and the other memory gate interconnection 7b is formed in the region of semiconductor substrate 1 that is positioned between the both end portions.

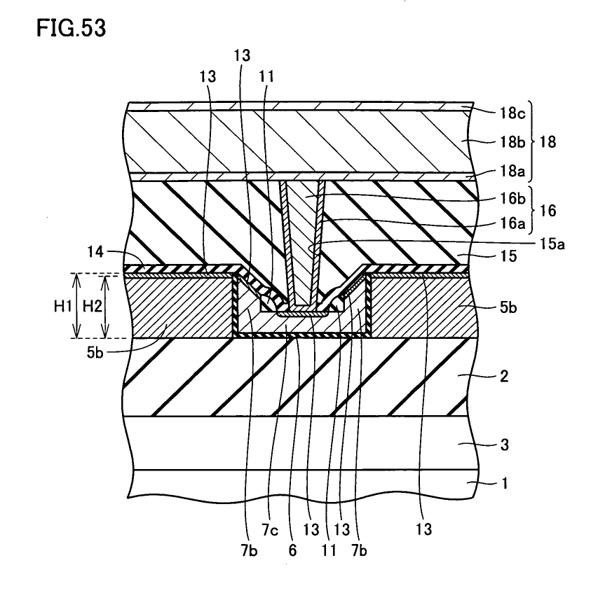

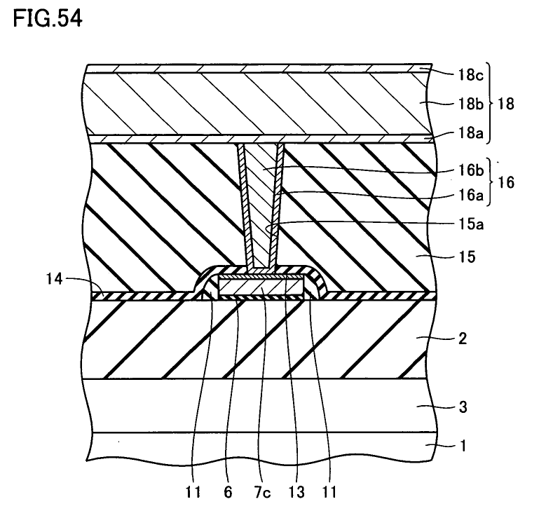

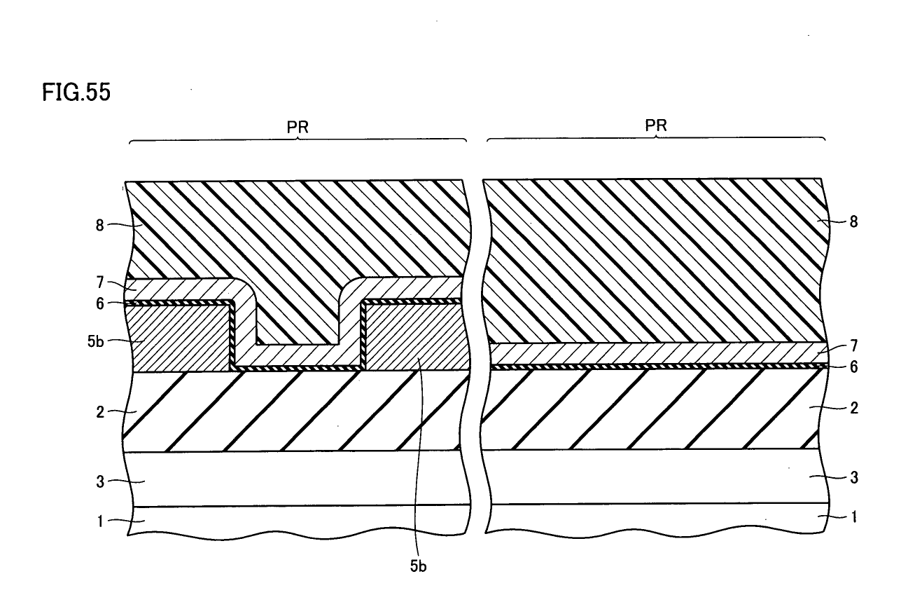

Now, as the structure of pad portion 7c and the region in the vicinity thereof, the structure in cross section taken along one direction (X direction) will be described first. As shown in FIG. 53, memory gate interconnection 7b is formed on each of the side surfaces of opposing control gate interconnections 5b, in the region of semiconductor substrate 1 that is sandwiched between the end portion of one control gate interconnection 5b and the end portion of the other control gate interconnection 5b. In addition, pad portion 7c is formed on the region of semiconductor substrate 1 that is sandwiched between those memory gate interconnections 7b with ONO film 6 interposed. On the other hand, in the structure in cross section taken along the direction (Y direction) orthogonal to the one direction, as shown in FIG. 54, pad portion 7c is formed on the surface of element isolation insulating film 2 with ONO film 6 interposed.

As shown in FIG. 53 and FIG. 54, metal silicide film 13 is formed on each surface of control gate interconnection 5b, memory gate interconnection 7b, pad portion 7c and the like. Interlayer insulating film 15 is formed on semiconductor substrate 1 with silicon nitride film 14 interposed to cover control gate interconnection 5b and the like. Plug 16 is formed in contact hole 15a formed in interlayer insulating film 15. In addition, interconnection 18 electrically connected to plug 16 is formed on interlayer insulating film 15. It is noted that the structure of the memory cell is similar to the forgoing one shown in FIG. 2 and FIG. 26, and therefore description thereof will not be repeated.

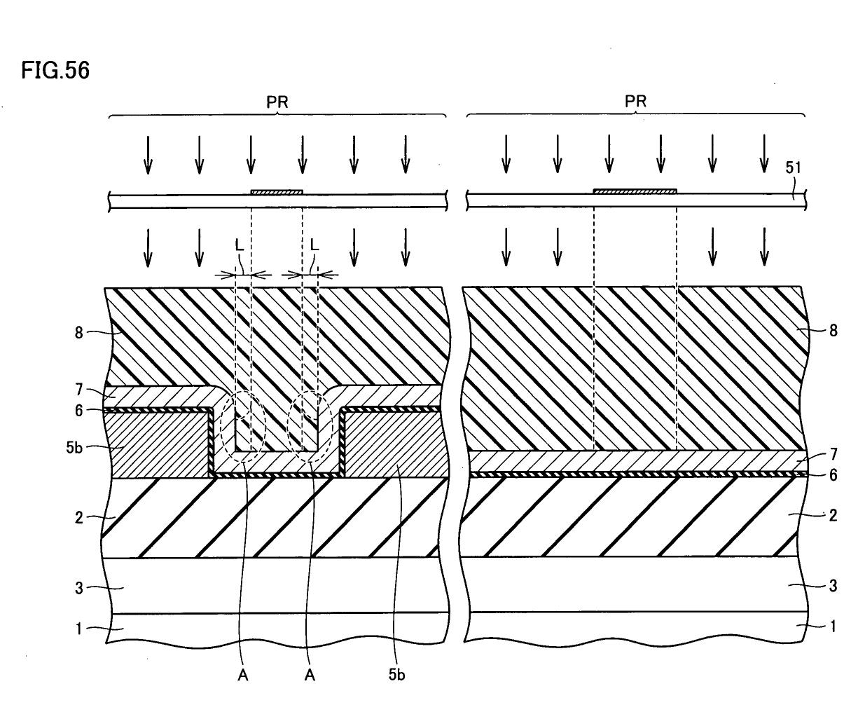

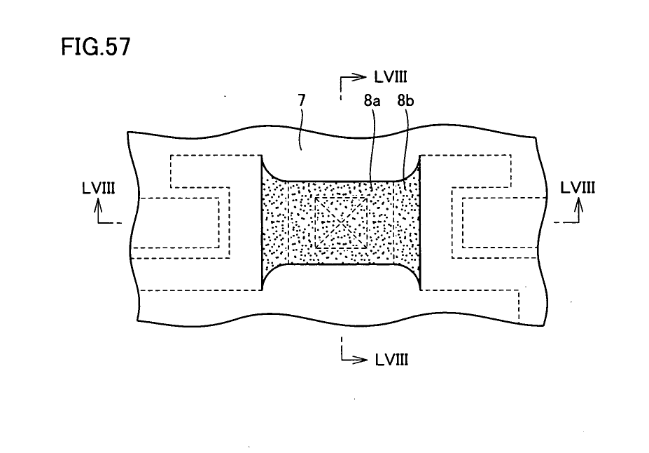

A method of manufacturing the nonvolatile semiconductor memory device as described above will now be described with reference to the cross sectional step view of peripheral circuit region PR. It is noted that the steps for the memory cell portion are similar to the foregoing steps, and therefore description thereof will not be repeated. First, through the steps similar to the steps shown in FIG. 7 and FIG. 8 as described above, as shown in FIG. 55, photoresist 8 for forming a pad portion is coated on polysilicon film 7. Then, as shown in FIG. 56, an exposure process is performed on photoresist 8 using prescribed mask 51.

Here, especially in the X direction, the exposure process is performed in such a manner that the photoresist is left due to poor resolution at part A of gap L between the original resist pattern for forming a pad portion and the part of polysilicon film 7 that covers each of the two end portions opposing to each other in control gate interconnection 5b.

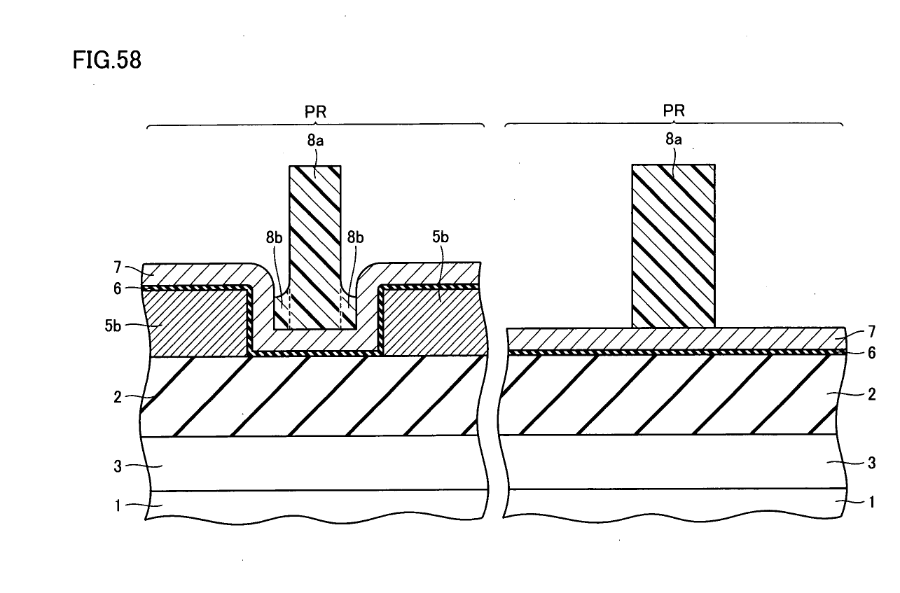

Then, a development process is performed on photoresist 8 subjected to the exposure process, resulting in resist patterns 8a, 8b as shown in FIG. 57 and FIG. 58. Resist pattern 8a is the original resist pattern for forming a pad portion, and resist pattern 8b is a resist pattern left due to poor resolution. The part of polysilicon film 7 that is positioned immediately under resist pattern 8b thus connects the part of polysilicon film 7 that is positioned immediately under resist pattern 8a to the part of polysilicon film 7 that is positioned on the side surface of control gate interconnection 5b.

Then, anisotropic etching is performed on polysilicon film 7 using resist patterns 8a, 8b as a mask, and in addition, through the steps similar to the steps shown in FIG. 12-FIG. 15 as described above, memory gate interconnection 7b is formed on one side surface of the part extending in one direction in control gate interconnection 5b, and pad portion 7c connected to memory gate interconnection 7b is formed in the region of the semiconductor substrate that is sandwiched between the end portion of one memory gate interconnection 7b and the end portion of the other memory gate interconnection 7b (see FIG. 52).

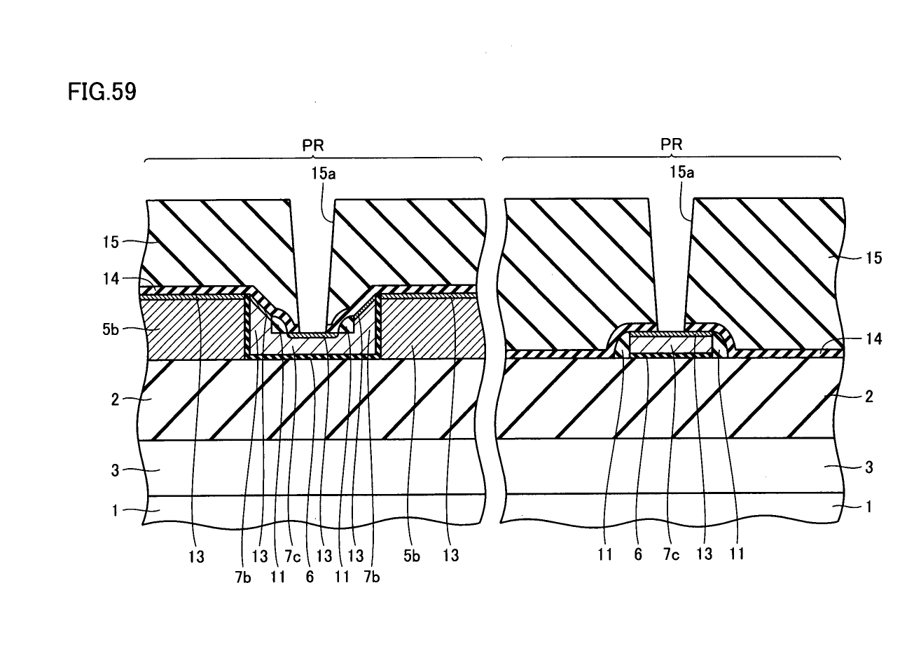

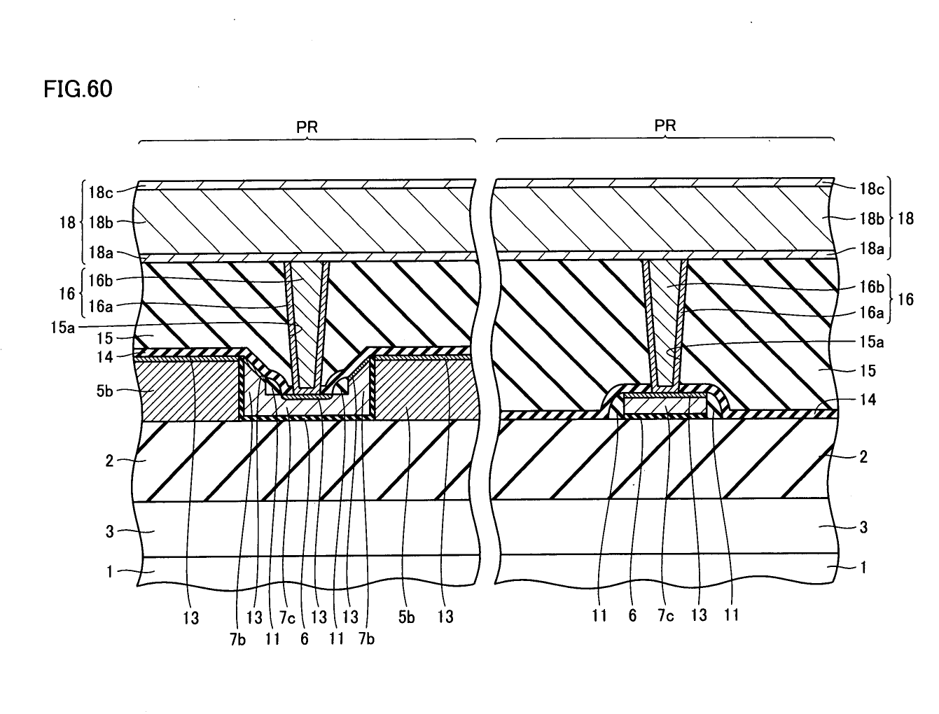

Then, through the steps similar to the steps shown in FIG. 16-FIG. 22 as described above, as shown in FIG. 59, contact hole 15a is formed to expose the surface of pad portion 7c. Then, through the steps similar to the steps shown in FIG. 23 and FIG. 24, as shown in FIG. 60, plug 16 is formed in contact hole 15a, and interconnection 18 electrically connected to plug 16 is formed. The main part of the nonvolatile semiconductor memory device is thus completed.

The nonvolatile semiconductor memory device as described above achieves the following effect in addition to the effect of increased process margin in resist pattern formation as described above. More specifically, pad portion 7c is formed in the region of the semiconductor substrate that is sandwiched between the end portion of one memory gate interconnection 7b and the end portion of the other memory gate interconnection 7b each extending along one straight line approximately extending in the X direction, so that the layout area (occupied area) can be reduced, as compared with the case where the pad portion is formed at a position in the Y direction with respect to the memory gate interconnection.

It is noted that although the semiconductor memory device as described above has been illustrated as a nonvolatile semiconductor memory device including a control gate electrode and a memory gate electrode by way of example, the present invention is applicable to a semiconductor device having a structure allowing a prescribed voltage to be applied to a second conductor portion formed on the side surface of a first conductor portion. Furthermore, although the control gate interconnection and the like and the memory gate interconnection and the like of the semiconductor memory device are formed using a polysilicon film in the foregoing illustration, the polysilicon film is illustrated only by way of example and a prescribed conductive material can be applied depending on a semiconductor memory device.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device comprising:
a first conductor portion formed on a surface of a semiconductor substrate to have a prescribed height and opposite side surfaces and extend in a first direction;
a second conductor portion formed on one side surface of said opposite side surfaces of said first conductor portion to be electrically separated from said first conductor portion and not to exceed said height of said first conductor portion;
an interlayer insulating film formed on said semiconductor substrate to cover said first conductor portion and said second conductor portion;
a contact member formed to pass through said interlayer insulating film; and
a first protrusion portion formed in said second conductor portion to extend from a part positioned on said one side surface of said first conductor portion to a side opposite to a side where said first conductor potion is positioned and to be in contact with said contact member so that a prescribed voltage is applied to said second conductor portion.

2. A semiconductor memory device comprising:
a first conductor portion formed on a surface of a semiconductor substrate to have a prescribed height and opposite side surfaces and extend in a first direction;
a second conductor portion formed on one side surface of said opposite side surfaces of said first conductor portion to be electrically separated from said first conductor portion;
an interlayer insulating film formed on said semiconductor substrate to cover said first conductor portion and said second conductor portion; and
a contact member formed to pass through said interlayer insulating film, wherein
said second conductor portion includes a first protrusion portion extending from a part positioned on said one side surface of said first conductor portion to a side opposite to a side where said first conductor portion is positioned and being in contact with said contact member so that a prescribed voltage is applied to said second conductor portion, and
a height of a part of said second conductor portion that is positioned on said one side surface is set to be at most said height of said first conductor portion such that said second conductor portion does not two-dimensionally overlap said first conductor portion.

3. The semiconductor memory device according to claim 2, wherein
said second conductor portion includes a pair of opposing portions formed to be spaced apart from and opposed to each other, and
said first protrusion portion is formed in a region sandwiched between said pair of opposing portions.

4. The semiconductor memory device according to claim 3, wherein
said second conductor portion includes, as said pair of opposing portions,
a second protrusion portion extending to a side opposite to a side where said first conductor portion is positioned and
a third protrusion portion extending to a side opposite to a side where said first conductor portion is positioned and being opposed to said second protrusion portion at a distance in said first direction.

5. The semiconductor memory device according to claim 3, wherein
a plurality of said first conductor portions and a plurality of said second conductor portions are formed, and
one second conductor portion and the other second conductor portion of a plurality of said second conductor portions are formed as said pair of opposing portions to be spaced apart from each other in a second direction orthogonal to said first direction.

6. The semiconductor memory device according to claim 3, wherein
a plurality of said first conductor portions and a plurality of said second conductor portions are formed, and
one second conductor portion and the other second conductor portion of a plurality of said second conductor portions are formed such that an end portion of said one second conductor portion and an end portion of said other second conductor portion are formed as said pair of opposing portions to be spaced apart from each other in said first direction.

7. The semiconductor memory device according to claim 2, wherein
said first conductor portion includes
a first gate electrode formed on said semiconductor substrate with a first gate insulating film interposed and
a first interconnection electrically connected to said first gate electrode,
said second conductor portion includes
a second gate electrode formed on said semiconductor substrate with a second gate insulating film interposed and on one side surface of said first gate electrode with a first insulating film interposed and
a second interconnection electrically connected to said second gate electrode, and
said semiconductor memory device further comprises:
a first impurity region of a prescribed conductivity type formed in a region of said semiconductor substrate that is positioned on a side opposite to a side where said second gate electrode is positioned with respect to said first gate electrode; and
a second impurity region of said prescribed conductivity type formed in a region of said semiconductor substrate that is positioned on a side opposite to a side where said first gate electrode is positioned with respect to said second gate electrode.

8. A method of manufacturing a semiconductor memory device comprising the steps of:
forming on a main surface of a semiconductor substrate a first conductor portion having a prescribed height and opposite side surfaces and extending in a first direction;
forming a conductive layer on a surface of said semiconductor substrate with a first insulating film interposed to cover said first conductor portion;
forming a resist pattern on said conductive layer by performing a photolithography process using a prescribed mask;
forming a voltage application portion for applying a prescribed voltage by performing processing on said conductive layer using said resist pattern as a mask;
leaving a part of said conductive layer that is positioned on a side of one side surface of said first conductor portion and removing a part of said conductive layer positioned in the other part thereby forming a second conductor portion including said voltage application portion on said one side surface of said first conductor portion with said first insulating film interposed;
forming an interlayer insulating film to cover said first conductor portion and said second conductor portion; and
forming an opening portion in said interlayer insulating film to expose said voltage application portion in said second conductor portion, and forming a contact member in said opening portion to be electrically connected to said voltage application portion, wherein
in said step of forming a resist pattern, an exposure process is performed on a resist coated on said semiconductor substrate such that the resist is left after development as a result of poor resolution, from the resist pattern left after development based on said prescribed mask to a part of said conductive layer that covers said one side surface of said first conductor portion, whereby a resist pattern is formed as said resist pattern including a resist pattern formed based on said prescribed mask as a first resist pattern and a resist left as a result of poor resolution as a second resist pattern.

9. The method of manufacturing a semiconductor memory device according to claim 8, wherein
said step of forming a first conductor portion includes the step of forming a pair of a first portion and a second portion spaced apart in said first direction, each extending in a second direction orthogonal to said first direction, and
in said step of forming a resist pattern, said resist pattern is formed to cover a part of said conductive layer that is positioned between a part of said conductive layer that covers said first portion and a part of said conductive layer that covers said second portion.

10. The method of manufacturing a semiconductor memory device according to claim 8, wherein
said step of forming a first conductor portion includes the steps of
forming a first gate electrode on said semiconductor substrate with a first gate insulating film interposed and
forming a first interconnection electrically connected to said first gate electrode,
said step of forming a second conductor portion includes the steps of
forming a second gate electrode on said semiconductor substrate with a second gate insulating film interposed and on one side surface of said first gate electrode with a first insulating film interposed and
forming a second interconnection electrically connected to said second gate electrode, and
said method further comprises the step of forming a first impurity region of a prescribed conductivity type in a region of said semiconductor substrate that is positioned on a side opposite to a side where said second gate electrode is positioned with respect to said first gate electrode, and forming a second impurity region of said prescribed conductivity type in a region of said semiconductor substrate that is positioned on a side opposite to a side where said first gate electrode is positioned with respect to said second gate electrode.
